(19) United States
(12) Patent Application Publication
(10) Pub. No.: US 2025/0221057 A1
(43) Pub. Date: Jul. 3, 2025

(54) AMBIENT LIGHT ENERGY HARVESTING DEVICE

(71) Applicant: QUALCOMM Incorporated, San Diego, CA (US)

(72) Inventors: Abhijeet PAUL, San Diego, CA (US); Mishel MATLOUBIAN, San Diego, CA (US); Periannan CHIDAMBARAM, San Diego, CA (US); Ravi Pramod Kumar VEDULA, San Diego, CA (US); Hyunchul JUNG, San Diego, CA (US)

(21) Appl. No.: 18/398,627

(22) Filed: Dec. 28, 2023

(51) Int. Cl. H01L 31/0475; H01L 31/0288; H01L 31/18

(52) U.S. Cl. CPC H10F 19/20; H10F 71/121; H10F 77/1223

(57) ABSTRACT

In an aspect, an ambient light energy harvesting device includes a semiconductor structure constituting at least a first diode of the ambient light energy harvesting device. The semiconductor structure includes a substrate portion of a first doping type, a first plurality of doped regions of the first doping type over the substrate portion, and a second plurality of doped regions of a second doping type over the substrate portion. The first plurality of doped regions and the second plurality of doped regions are arranged in an alternating manner along a lateral direction.

### TECHNICAL FIELD

The present disclosure generally relates to an ambient light energy harvesting device included in an integrated circuit (IC) die, and more particularly to an ambient light energy harvesting device that includes a semiconductor structure constituting at least a diode including lateral p-n junctions and vertical p-n junctions.

### BACKGROUND

The Internet of Things (IoT) is based on the idea that everyday objects, not just computers and computer networks, can be readable, recognizable, locatable, addressable, and controllable via an IoT communications network (e.g., an ad-hoc system or the Internet). There are a number of key applications for the IoT. For example, in the area of smart grids and energy management, utility companies can optimize delivery of energy to homes and businesses while customers can better manage energy usage. In the area of home and building automation, smart homes and buildings can have centralized control over virtually any device or system in the home or office, from appliances to plug-in electric vehicle (PEV) security systems. In the field of asset tracking, enterprises, hospitals, factories, and other large organizations can accurately track the locations of high-value equipment, patients, vehicles, and so on. In the area of health and wellness, doctors can remotely monitor patients' health while people can track the progress of fitness routines.

In some applications, an IoT device may be a sensing device that may be placed at a location that may not have convenient access to an external power source. In some applications, providing power connection or even a battery to such sensing IoT device may not be feasible or practical. For example, the battery may have a finite lifespan, and it may be difficult (technically or financially) to replace the battery once the battery runs out. Connecting a power cable to such sensing IoT device may be infeasible or costly if the sensing IoT device is placed at a remote location. Similarly, establishing a separate power generator (even a solar and/or wind power generator) may be too bulky and/or may incur too much extra cost (time and/or money) just for the sensing IoT device. Therefore, such sensing IoT device may be configured to operate on a low power and may be self-powered.

Accordingly, there is a need for an integrated circuit (IC) die for a sensing IoT device that incorporates an energy harvesting device, such as an ambient light energy harvesting device, and a method of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an ambient light energy harvesting device includes a semiconductor structure constituting at least a first diode of the ambient light energy harvesting device, the semiconductor structure comprising: a substrate portion of a first doping type; a first plurality of doped regions of the first doping type over the substrate portion; and a second plurality of doped regions of a second doping type over the substrate portion, wherein: the first plurality of doped regions and the second plurality of doped regions are arranged in an alternating manner along a lateral direction.

In an aspect, a method of manufacturing an ambient light energy harvesting device includes forming a semiconductor structure constituting at least a first diode of the ambient light energy harvesting device, comprising: forming a first plurality of doped regions of a first doping type over a substrate portion; and forming a second plurality of doped regions of a second doping type over the substrate portion, wherein: the first plurality of doped regions and the second plurality of doped regions are arranged in an alternating manner along a lateral direction.

In an aspect, an electronic device includes an integrated circuit (IC) die that includes processing circuitry and a first ambient light energy harvesting device configured to supply power to the processing circuitry, wherein the first ambient light energy harvesting device comprises a semiconductor structure constituting at least a first diode of the first ambient light energy harvesting device, and the semiconductor structure comprises: a substrate portion of a first doping type; a first plurality of doped regions of the first doping type over the substrate portion; and a second plurality of doped regions of a second doping type over the substrate portion, wherein: the first plurality of doped regions and the second plurality of doped regions are arranged in an alternating manner along a lateral direction.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates an example Internet of Things (IoT) device that can be powered by ambient light, according to aspects of the disclosure.

FIGS. 1B and 1C illustrate example integrated circuit (IC) dies for an IoT device, according to aspects of the disclosure.

FIG. 2A is a top view of a portion of an example ambient light energy harvesting device, according to aspects of the disclosure.

FIGS. 2B and 2C are cross-sectional views of a portion of a semiconductor structure constituting at least a first example ambient light energy harvesting diode, according to aspects of the disclosure.

FIGS. 3A and 3B are cross-sectional views of a portion of a semiconductor structure constituting at least a second example ambient light energy harvesting diode, according to aspects of the disclosure.

FIGS. 4A and 4B are cross-sectional views of a portion of a semiconductor structure constituting at least a third example ambient light energy harvesting diode, according to aspects of the disclosure.

FIGS. 5A and 5B are cross-sectional views of a portion of a semiconductor structure constituting at least a fourth example ambient light energy harvesting diode, according to aspects of the disclosure.

FIGS. 6A-6D illustrate current-voltage diagrams and power-voltage diagrams of various example ambient light energy harvesting diodes, according to aspects of the disclosure.

FIGS. 7A-7C illustrate example configurations of ambient light energy harvesting devices, according to aspects of the disclosure.

FIGS. 8A-8D illustrate example isolation structures for one or more ambient light energy harvesting devices, according to aspects of the disclosure.

FIG. 9A is a simplified top view of an IC die that incorporates an example ambient light energy harvesting device, according to aspects of the disclosure.

FIGS. 9B and 9C are simplified cross-sectional views of the IC die in FIG. 9A configured to receive the ambient light based on different approaches, according to aspects of the disclosure.

FIGS. 10A and 10B illustrate example semiconductor structures with isolation structures from which an ambient light energy harvesting device may be formed, according to aspects of the disclosure.

FIGS. 11A-11C illustrate structures at various stages of manufacturing a semiconductor structure for an ambient light energy harvesting device, according to aspects of the disclosure.

FIGS. 12A-12B illustrate structures at various stages of manufacturing a semiconductor structure for an ambient light energy harvesting device, according to aspects of the disclosure.

FIGS. 13A-13C illustrate structures at various stages of manufacturing a semiconductor structure for an ambient light energy harvesting device, according to aspects of the disclosure.

FIGS. 14A-14C illustrate structures at various stages of manufacturing a semiconductor structure for an ambient light energy harvesting device, according to aspects of the disclosure.

FIG. 15 illustrates a method for manufacturing an ambient light energy harvesting device, according to aspects of the disclosure.

FIG. 16 illustrates a mobile device, according to aspects of the disclosure.

FIG. 17 illustrates various electronic devices that may incorporate an IC die with an ambient light energy harvesting device included therein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to manufacturing an ambient light energy harvesting device in an integrated circuit (IC) die of an Internet of Things (IoT) device, where the ambient light energy harvesting device may include doped regions, substrate portion, and/or buried doped structures defining lateral p-n junctions and vertical p-n junctions at various depths.

Particular aspects of the subject matter described in this disclosure can be implemented to realize one or more of the following potential advantages. In some examples, the resulting ambient light energy harvesting device may be configured to be responsive to a wide range of wavelengths of light. Also, the combination of all the lateral p-n junctions and vertical p-n junctions may enhance the light sensitivity of a diode of the ambient light energy harvesting device by 10 times compared with a diode in the same footprint with only vertical p-n junctions.

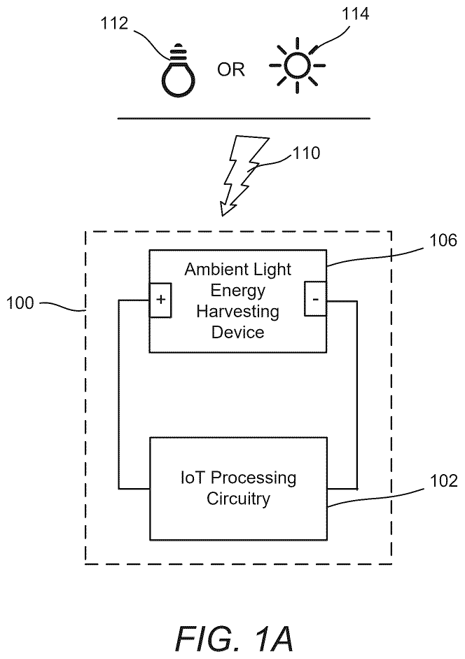

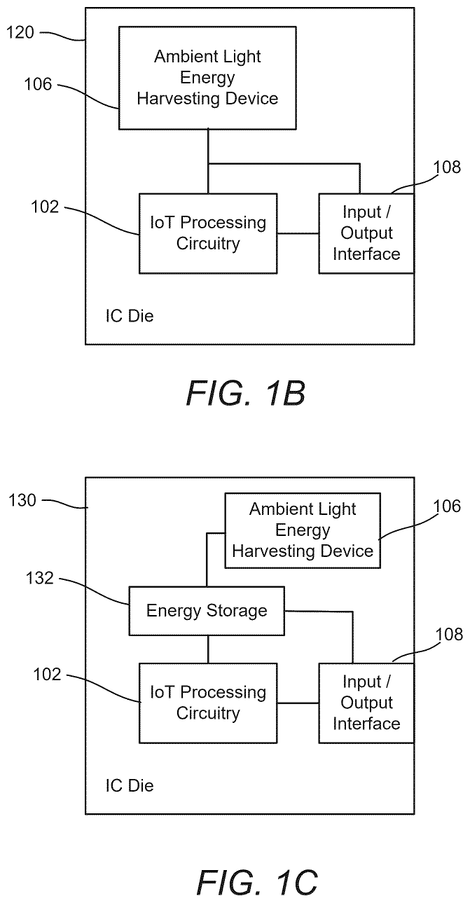

FIG. 1A illustrates an example IoT device 100 that can be powered by ambient light 110, according to aspects of the disclosure. In some aspects, the IoT device 100 may include IoT processing circuitry 102 and an ambient light energy harvesting device 106. In some aspects, the IoT processing circuitry 102 may include analog processing circuitry and/or digital processing circuitry. In some aspects, the IoT processing circuitry 102 may further include sensing components configured to sense various environmental parameters such that the IoT device 100 based on the sensing components may be configured as one or more of a light sensor, a temperature sensor, a humidity sensor, a gyroscope, an accelerometer, an electrical field sensor, a magnetic field sensor, or the like.

In some aspects, the ambient light energy harvesting device 106 may convert the ambient light 110 it receives into electrical energy usable to power the processing circuitry 102. In some aspects, the ambient light 110 may come from an artificial light source 112 (e.g., light bulbs, candles, fire, laser, etc.) or a natural light source 114 (e.g., the sun, the moon, lightening, bioluminescence, biofluorescence, etc.). Accordingly, the IoT device 100 may be self-powered based on the ambient light 110. In some aspects, the IoT processing circuitry 102 and the ambient light energy harvesting device 106 may be integrated in the same IC die.

FIG. 1B illustrates a first example IC die 120 for an IoT device, according to aspects of the disclosure. In this example, the IC die 120 may include the IoT processing circuitry 102, the ambient light energy harvesting device 106, and an input and/or output interface 108 formed in the IC die 120. In some aspects, the input and/or output interface 108 may be configured to communicate with an external device based on a wired connection or a wireless connection. In some aspects, the ambient light energy harvesting device 106 may directly power the IoT processing circuitry 102 and the input and/or output interface 108.

Also, FIG. 1C illustrates a second example IC die 130 for an IoT device, according to aspects of the disclosure. In this example, the IC die 130 may include the IoT processing circuitry 102, the ambient light energy harvesting device 106, and an input and/or output interface 108 formed in the IC die 120. In this example, the IC die 130 may further include an energy storage 132, such as a rechargeable battery, a capacitor, or a super capacitor. In some aspects, the input and/or output interface 108 may be configured to communicate with an external device based on a wired connection or a wireless connection. In some aspects, the ambient light energy harvesting device 106 may not directly power the IoT processing circuitry 102 and the input and/or output interface 108. Instead, in this example, the energy storage 132 may receive the electric energy from the ambient light energy harvesting device 106 and store the received electrical energy therein. In some aspects, the energy storage 132 may power the IoT processing circuitry 102 and the input and/or output interface 108 based on the stored electric energy such that the energy supply may be more stable and consistent regardless of the fluctuation of the ambient light.

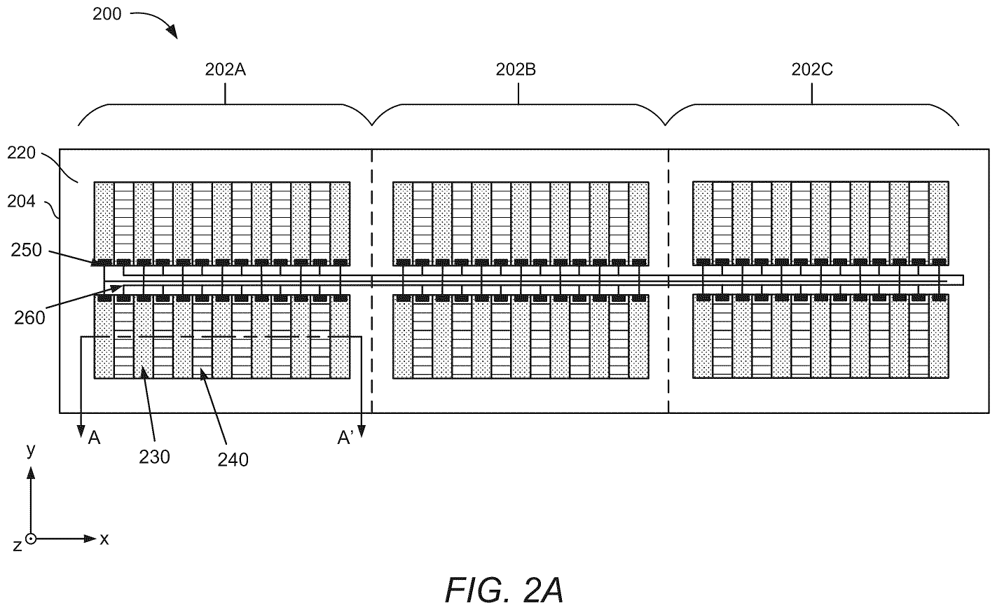

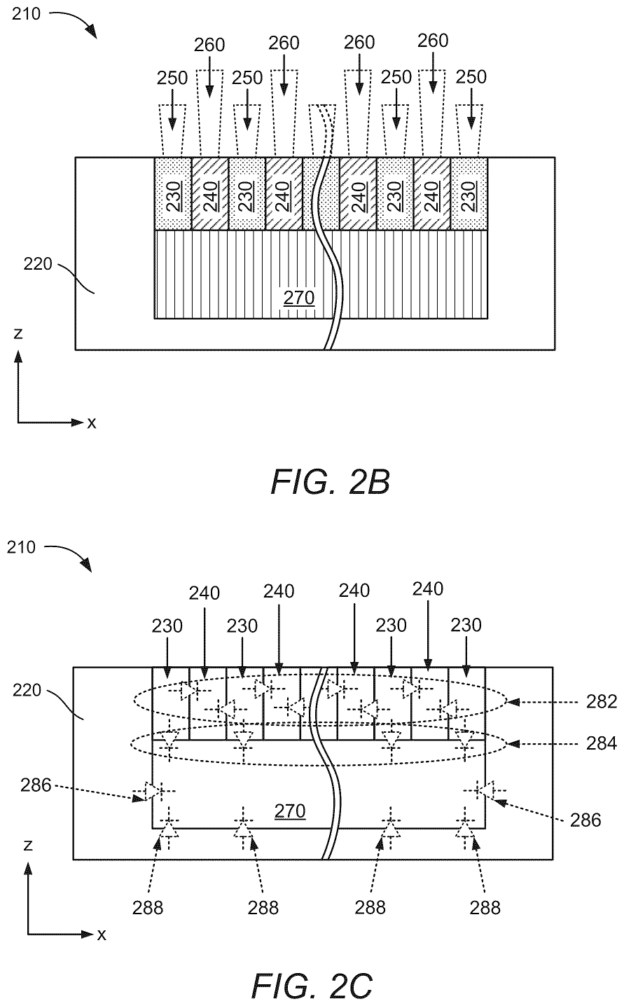

FIG. 2A is a top view of a portion of an example ambient light energy harvesting device 200, according to aspects of the disclosure. In some aspects, the ambient light energy harvesting device 200 may correspond to the ambient light energy harvesting device 106 and may be incorporated in the IC die 120 or the IC die 130 as a part of the IoT device 100 as shown in FIGS. 1A-1C. In some aspects, FIG. 2A is a simplified top view of the ambient light energy harvesting device 200, and certain details and components of the ambient light energy harvesting device 200 may be simplified or omitted in FIG. 2A.

In some aspects, the ambient light energy harvesting device 200 may include a semiconductor structure constituting one or more ambient light energy harvesting diodes (e.g., three semiconductor structure portions 202A, 202B, and 202C in FIG. 2A constituting to three diodes, respectively) and may be surrounded by an electrical guard ring structure 204. In some aspects, the semiconductor structure portions 202A, 202B, and 202C may have similar structural features and may be electrically connected in parallel or in series.

As shown in FIG. 2A, the semiconductor structure portion 202A may include a substrate portion 220 of a first doping type, a first plurality of doped regions 230 (the regions having the same pattern as indicated by reference number 230) of the first doping type over the substrate portion 220, and a second plurality of doped regions 240 (the regions having the same pattern as indicated by reference number 240) of a second doping type over the substrate portion 220. In some aspects, the semiconductor structure portion 202A may include a first conductive structure 250 electrically coupled to the first plurality of doped regions 230 and a second conductive structure 260 electrically coupled to the second plurality of doped regions 240. In some aspects, the first conductive structure 250 and the second conductive structure 260 may include conductive lines extending along a lateral direction (e.g., the direction x or the direction y) and vias extending along a vertical direction (e.g., the direction z).

In some aspects, the semiconductor structure portions 202A, 202B, and 202C may include silicon as the base material. In some aspects, the first doping type may be a p-doping type, and the second doping type may be an n-doping type. In some aspects, the first doping type may be the n-doping type, and the second doping type may be the p-doping type. In some aspects, the substrate portion 220 may include silicon with a dopant concentration ranging from 10×10¹² cm⁻³ to 10×10¹⁴ cm³. In some aspects, one of the first doping type and the second doping type may be a p-doping type based on dopants that comprise arsenic (As), phosphorus (P), antimony (Sb), or a combination thereof. In some aspects, the other one of the first doping type and the second doping type is an n-doping type based on dopants that comprise boron (B), boron difluoride (BF₂), indium (In), or a combination thereof.

In some aspects, the semiconductor structure portion 202A is illustrated as non-limiting examples, and the semiconductor structure portions 202B and 202C may be similar to the semiconductor structure portion 202A. In some aspects, variations of the semiconductor structure corresponding to different example ambient light energy harvesting diodes are illustrated based on cross-sectional views of the example diodes in FIGS. 2B-5B taken along the line A-A′ in FIG. 2A.

FIGS. 2B and 2C are cross-sectional views of a portion of a semiconductor structure 210 constituting at least a first example ambient light energy harvesting diode (which may correspond to the semiconductor structure portion 202A in FIG. 2A), according to aspects of the disclosure. FIG. 2B illustrates the structural features of the first example ambient light energy harvesting diode, and FIG. 2C illustrates the p-n junctions of the first example ambient light energy harvesting diode, according to aspects of the disclosure. The components in FIGS. 2B and 2C that are the same or similar to those in FIG. 2A are given the same reference numbers, and detail description thereof may be simplified or omitted.

As shown in FIG. 2B, the semiconductor structure 210 may include a buried doped structure 270 of the second doping type. In some aspects, buried doped structure 270 may be disposed under and in contact with the lower surfaces of the first plurality of doped regions 230 and the lower surfaces of the second plurality of doped regions 240. In some aspects, the buried doped structure 270 may be a buried doped layer on and in contact with at least a portion of the substrate portion 220.

As shown in FIG. 2C, the first plurality of doped regions 230 and the second plurality of doped regions 240 may be arranged in an alternating manner along a lateral direction (e.g., the x direction) and configured to define lateral p-n junctions 282 (depicted as diodes in dotted lines) between the first plurality of doped regions 230 and the second plurality of doped regions 240. In some aspects, based on the buried doped structure 270 of the second doping type being under and in contact with the lower surfaces of the first plurality of doped regions 230 and the lower surfaces of the second plurality of doped regions 240, the first plurality of doped regions 230 and the buried doped structure 270 further define vertical p-n junctions 284 (depicted as diodes in dotted lines). In some aspects, the substrate portion 220 and the buried doped structure 270 may define additional lateral p-n junctions 286 (depicted as diodes in dotted lines) and additional vertical p-n junctions 288 (depicted as diodes in dotted lines). In some aspects, the p-n junctions 282, 284, 286, and 288 may be configured to convert received light energy to electrical energy based on a photovoltaic effect.

In some aspects, the polarities of the p-n junctions in FIG. 2C are depicted as a non-limiting example. The actual polarities of the p-n junctions in FIG. 2C may be defined based on the first doping type and the second doping type as implemented.

In some aspects, different wavelengths of light may have different depths of penetration in a semiconductor material. In some aspects, for using silicon as the base material, the light with a wavelength of about 380 nanometers (nm) (e.g., violet) may have a penetration depth of about 0.01 μm; the light with a wavelength of about 550 nm (e.g., green) may have a penetration depth of about 0.12 μm; and the light with a wavelength of about 700 nm (e.g., red) may have a penetration depth of about 0.5 μm.

Accordingly, as a non-limiting example, the p-n junctions formed closer to an upper surface of the first plurality of doped regions 230 and the second plurality of doped regions 240 (e.g., the lateral p-n junctions 282) may be responsive to the light with a wavelength of about 380 nm; the p-n junctions formed farther away from the upper surface of the first plurality of doped regions 230 and the second plurality of doped regions 240 (e.g., the lateral p-n junctions 286 and the vertical junctions 288) may be responsive to the light with a wavelength of about 700 nm; and the p-n junctions formed with an intermediate depth (e.g., the vertical p-n junctions 284) may be responsive to the light with a wavelength of about 550 nm. In some aspects, a thickness of the first plurality of doped regions 230 and the second plurality of doped regions 240 may range from 0.2 to 0.4 micrometers (μm). In some aspects, a thickness of the buried doped structure ranges from 0.4 to 0.6 μm.

Therefore, the structure as shown in FIGS. 2B and 2C may be configured to be responsive to a wide range of wavelengths of light. In some aspects, the structure as shown in FIGS. 2B and 2C may have a good area efficiency by forming the lateral p-n junctions 282 based on the alternating doped regions 230 and 240. Also, additional vertical p-n junctions 284 may be formed between the doped regions 230 and the buried doped structure 270. In some aspects, the combination of all these p-n junctions shown in FIG. 2C may enhance the light sensitivity by 10 times or more compared with a diode in the same footprint with only vertical junctions.

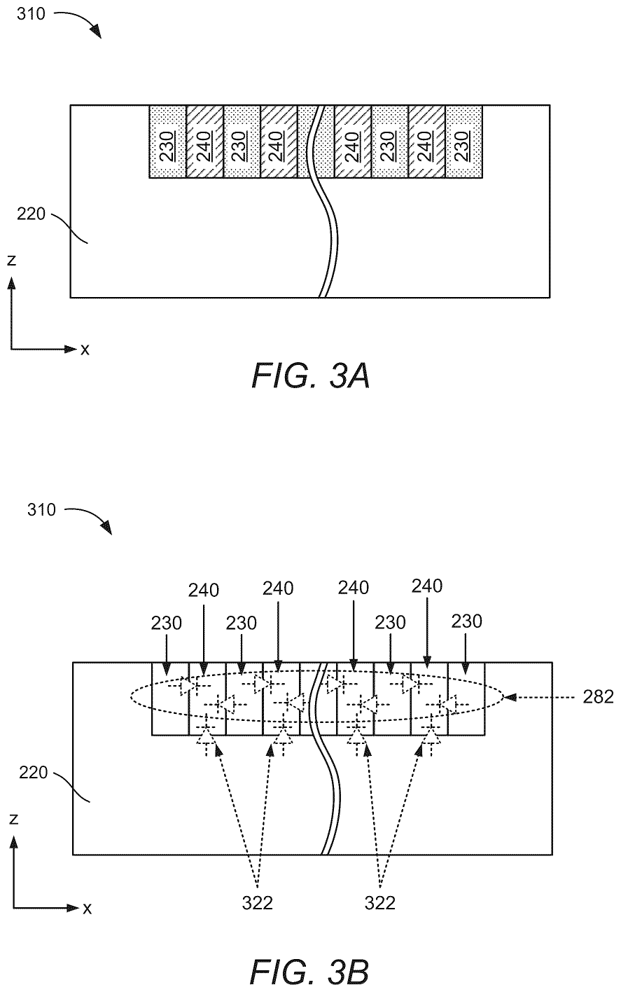

FIGS. 3A and 3B are cross-sectional views of a portion of a semiconductor structure 310 constituting a second example ambient light energy harvesting diode (which may correspond to the semiconductor structure portion 202A in FIG. 2A), according to aspects of the disclosure. FIG. 3A illustrates the structural features of the second example ambient light energy harvesting diode, and FIG. 3B illustrates the p-n junctions of the second example ambient light energy harvesting diode, according to aspects of the disclosure. In some aspects, the semiconductor structure 310 may be a variation of the semiconductor structure 210. The components in FIGS. 3A and 3B that are the same or similar to those in FIGS. 2B and 2C are given the same reference numbers, and detail description thereof may be simplified or omitted.

As shown in FIG. 3A, compared with the semiconductor structure 210 in FIG. 2B, the semiconductor structure 310 may not have the buried doped structure 270. Therefore, in some aspects, the lower surfaces of the first plurality of doped regions 230 and the lower surfaces of the second plurality of doped regions 240 may be on and in contact with the substrate portion 220.

As shown in FIG. 3B, the first plurality of doped regions 230 and the second plurality of doped regions 240 may be arranged in an alternating manner along a lateral direction (e.g., the x direction) and configured to define lateral p-n junctions 282 (depicted as diodes in dotted lines) between the first plurality of doped regions 230 and the second plurality of doped regions 240. In some aspects, based on the lower surfaces of the first plurality of doped regions 230 and the lower surfaces of the second plurality of doped regions 240 being in contact with at least a portion of the substrate portion 220, the second plurality of doped regions 240 and the substrate portion 220 may define vertical p-n junctions 322 (depicted as diodes in dotted lines). In some aspects, the p-n junctions 282 and 322 may be configured to convert received light energy to electrical energy based on a photovoltaic effect.

In some aspects, the polarities of the p-n junctions in FIG. 3B are depicted as a non-limiting example. The actual polarities of the p-n junctions in FIG. 3B may be defined based on the first doping type and the second doping type as implemented.

In some aspects, as a non-limiting example, the thickness of the first plurality of doped regions 230 and the second plurality of doped regions 240 may be sufficiently great to allow the lateral p-n junctions 282 to be responsive to the light with a wavelength ranging from 380 nm to 700 nm. In some aspects, a thickness of the first plurality of doped regions 230 and the second plurality of doped regions 240 may range from 0.4 to 0.8 μm.

Therefore, the structure as shown in FIGS. 3A and 3B may be configured to be responsive to a wide range of wavelengths of light. In some aspects, the structure as shown in FIGS. 3A and 3B may have a good area efficiency by forming the lateral p-n junctions 282 based on the alternating doped regions 230 and 240. Also, additional vertical p-n junctions 322 may be formed between the doped regions 240 and the substrate portion 220. In some aspects, the combination of all these p-n junctions shown in FIG. 3B may enhance the light sensitivity by 10 times or more compared with a diode in the same footprint with only vertical junctions.

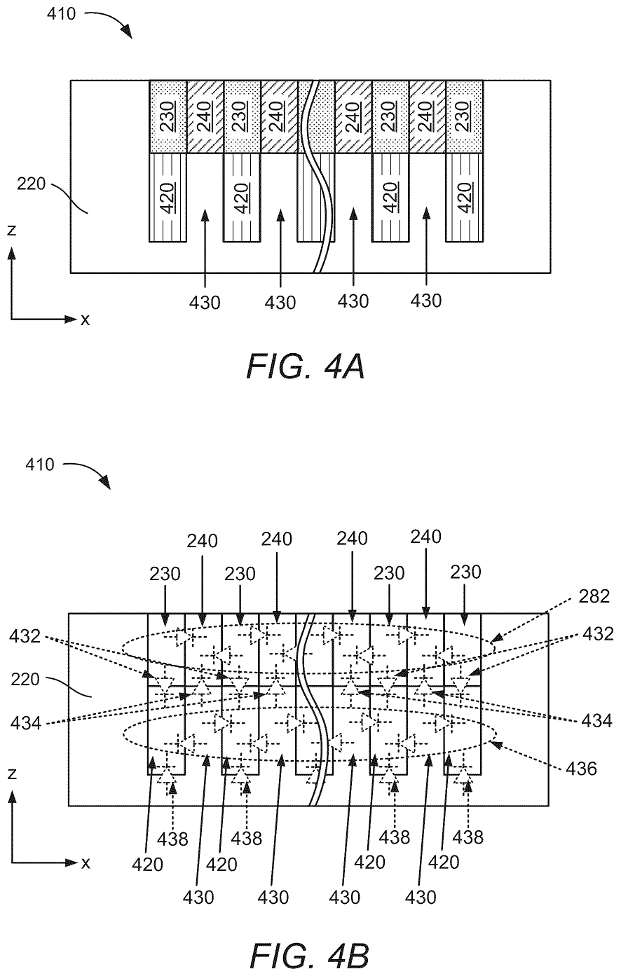

FIGS. 4A and 4B are cross-sectional views of a portion of a semiconductor structure 410 constituting at least a third example ambient light energy harvesting diode (which may correspond to the semiconductor structure portion 202A in FIG. 2A), according to aspects of the disclosure. FIG. 4A illustrates the structural features of the third example ambient light energy harvesting diode, and FIG. 3B illustrates the p-n junctions of the third example ambient light energy harvesting diode, according to aspects of the disclosure. In some aspects, the semiconductor structure 410 may be a variation of the semiconductor structure 210. The components in FIGS. 4A and 4B that are the same or similar to those in FIGS. 2B and 2C are given the same reference numbers, and detail description thereof may be simplified or omitted.

As shown in FIG. 4A, compared with the semiconductor structure 210 in FIG. 2B, the buried doped structure 270 may be replaced with the buried doped structure 420, which may include a plurality of buried doped fingers on and in contact with at least a portion of the substrate portion 220. Also, the substrate portion 220 may include a plurality of substrate fingers 430 between respective ones of the buried doped fingers. In some aspects, the plurality of buried doped fingers (e.g., the buried doped structure 420) and the plurality of substrate fingers 430 may be arranged in an alternating manner along the lateral direction (e.g., the x direction). As shown in FIG. 4A, each one of the lower surfaces of the first plurality of doped regions 230 is in contact with a respective one of the plurality of buried doped fingers of the buried doped structure 420. Also, each one of the lower surfaces of the second plurality of doped regions 240 is in contact with the substrate portion 220 (e.g., in contact with a respective one of the plurality of substrate fingers 430).

As shown in FIG. 4B, the first plurality of doped regions 230 and the second plurality of doped regions 240 may be arranged in an alternating manner along a lateral direction (e.g., the x direction) and configured to define lateral p-n junctions 282 (depicted as diodes in dotted lines) between the first plurality of doped regions 230 and the second plurality of doped regions 240. In some aspects, based on the lower surfaces of the first plurality of doped regions 230 being on and in contact with the buried doped structure 420, the first plurality of doped regions 230 and the buried doped structure 420 may define vertical p-n junctions 432 (depicted as diodes in dotted lines) therebetween. In some aspects, based on the lower surfaces of the second plurality of doped regions 240 being on and in contact with the plurality of substrate fingers 430 of the substrate portion 220, the second plurality of doped regions 240 and the substrate portion 220 may define vertical p-n junctions 434 (depicted as diodes in dotted lines) therebetween.

As shown in FIG. 4B, the plurality of buried doped fingers of the buried doped structure 420 and the plurality of substrate fingers 430 of the substrate portion 220 may define lateral p-n junctions 436 (depicted as diodes in dotted lines) therebetween. Also, the substrate portion 220 and the lower surfaces of the plurality of buried doped fingers of the buried doped structure 420 may define vertical p-n junctions 438 (depicted as diodes in dotted lines) therebetween. In some aspects, the p-n junctions 282, 432, 434, 436, and 438 may be configured to convert received light energy to electrical energy based on a photovoltaic effect.

In some aspects, the polarities of the p-n junctions in FIG. 4B are depicted as a non-limiting example. The actual polarities of the p-n junctions in FIG. 4B may be defined based on the first doping type and the second doping type as implemented.

In some aspects, as a non-limiting example, a thickness of the first plurality of doped regions 230 and the second plurality of doped regions 240 may range from 0.2 to 0.4 μm. In some aspects, a thickness of the buried doped structure 420 may range from 0.4 to 0.6 μm. Therefore, the structure as shown in FIGS. 4A and 4B may be configured to define lateral p-n junctions and vertical p-n junctions at various depths such that the diode based on the structure 410 may be responsive to a wide range of wavelengths of light. Also, the structure as shown in FIGS. 4A and 4B may have a good area efficiency by forming the lateral p-n junctions 282 based on the alternating doped regions 230 and 240. In some aspects, additional lateral p-n junctions and additional vertical p-n junctions may be formed between the doped regions 230, the buried doped structure 420, and the substrate portion 220/430. In some aspects, the combination of all these p-n junctions shown in FIG. 4B may enhance the light sensitivity by 10 times or more compared with a diode in the same footprint with only vertical junctions.

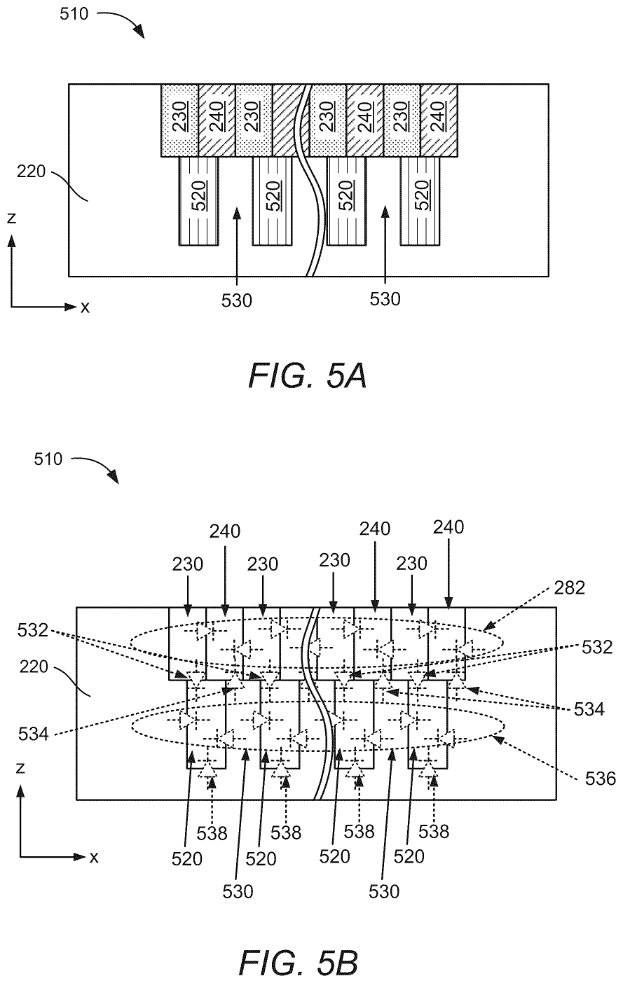

FIGS. 5A and 5B are cross-sectional views of a portion of a semiconductor structure 510 constituting at least a fourth example ambient light energy harvesting diode (which may correspond to the semiconductor structure portion 202A in FIG. 2A), according to aspects of the disclosure. FIG. 5A illustrates the structural features of the fourth example ambient light energy harvesting diode, and FIG. 5B illustrates the p-n junctions of the fourth example ambient light energy harvesting diode, according to aspects of the disclosure. In some aspects, the semiconductor structure 510 may be a variation of the semiconductor structure 410. The components in FIGS. 5A and 5B that are the same or similar to those in FIGS. 4A and 4B are given the same reference numbers, and detail description thereof may be simplified or omitted.

As shown in FIG. 5A, compared with the semiconductor structure 410 in FIG. 4A, the buried doped structure 420 may be replaced with the buried doped structure 520, which may include a plurality of buried doped fingers on and in contact with at least a portion of the substrate portion 220. Also, the substrate portion 220 may include a plurality of substrate fingers 530 between respective ones of the buried doped fingers. In some aspects, the plurality of buried doped fingers (e.g., the buried doped structure 520) and the plurality of substrate fingers 530 may be arranged in an alternating manner along the lateral direction (e.g., the x direction). As shown in FIG. 5A, each one of the lower surfaces of the first plurality of doped regions 230 may be in contact with a respective portion of the plurality of buried doped fingers of the buried doped structure 520 and a respective portion of the plurality of substrate fingers 530. Also, each one of the lower surfaces of the second plurality of doped regions 240 may be in contact with a respective portion of the plurality of buried doped fingers of the buried doped structure 520 and a respective portion of the plurality of substrate fingers 530.

As shown in FIG. 5B, the first plurality of doped regions 230 and the second plurality of doped regions 240 may be arranged in an alternating manner along a lateral direction (e.g., the x direction) and configured to define lateral p-n junctions 282 (depicted as diodes in dotted lines) between the first plurality of doped regions 230 and the second plurality of doped regions 240. In some aspects, based on the lower surfaces of the first plurality of doped regions 230 being on and in contact with respective portions of the buried doped structure 420, the first plurality of doped regions 230 and the buried doped structure 520 may define vertical p-n junctions 532 (depicted as diodes in dotted lines) therebetween. In some aspects, based on the lower surfaces of the second plurality of doped regions 240 being on and in contact with respective portions of the plurality of substrate fingers 530 of the substrate portion 220, the second plurality of doped regions 240 and the substrate portion 220 may define vertical p-n junctions 534 (depicted as diodes in dotted lines) therebetween.

As shown in FIG. 5B, the plurality of buried doped fingers of the buried doped structure 520 and the plurality of substrate fingers 530 of the substrate portion 220 may define lateral p-n junctions 536 (depicted as diodes in dotted lines) therebetween. Also, the substrate portion 220 and the lower surfaces of the plurality of buried doped fingers of the buried doped structure 520 may define vertical p-n junctions 538 (depicted as diodes in dotted lines) therebetween. In some aspects, the p-n junctions 282, 532, 534, 536, and 538 may be configured to convert received light energy to electrical energy based on a photovoltaic effect.

In some aspects, the polarities of the p-n junctions in FIG. 5B are depicted as a non-limiting example. The actual polarities of the p-n junctions in FIG. 5B may be defined based on the first doping type and the second doping type as implemented.

In some aspects, as a non-limiting example, a thickness of the first plurality of doped regions 230 and the second plurality of doped regions 240 may range from 0.2 to 0.4 μm. In some aspects, a thickness of the buried doped structure 520 may range from 0.4 to 0.6 μm. Therefore, the structure as shown in FIGS. 5A and 5B may be configured to define lateral p-n junctions and vertical p-n junctions at various depths such that the diode based on the structure 510 may be responsive to a wide range of wavelengths of light. Also, the structure as shown in FIGS. 5A and 5B may have a good area efficiency by forming the lateral p-n junctions 282 based on the alternating doped regions 230 and 240. In some aspects, additional lateral p-n junctions and additional vertical p-n junctions may be formed between the doped regions 230, the buried doped structure 520, and the substrate portion 220/530. In some aspects, the combination of all these p-n junctions shown in FIG. 5B may enhance the light sensitivity by 10 times compared with a diode in the same footprint with only vertical junctions.

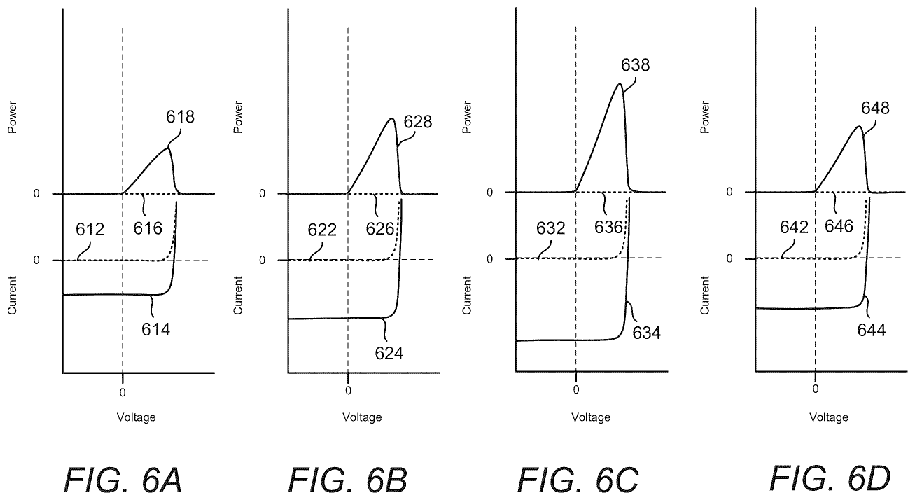

FIGS. 6A-6D illustrate current-voltage diagrams and power-voltage diagrams of various example ambient light energy harvesting diodes, according to aspects of the disclosure. In some aspects, the examples in FIGS. 6A-6D are based on the first doping type being the p-doping type, and the second doping type being the n-doping type. In some aspects, the current-voltage diagrams may be based on a light source with 4000 lux of light density (also known as illuminance).

Each of FIGS. 6A-6D includes a respective power-voltage diagram in an upper portion and a respective current-voltage diagram in a lower portion thereof. For the current-voltage diagram part, the horizontal axis represents voltage (in volts or V), and the vertical axis represents current (in microamperes or μA). For the power-voltage diagram part, the horizontal axis represents voltage (in volts or V), and the vertical axis represents power (in microwatts or μW).

As shown in FIG. 6A, curve 612 represents a current-voltage relationship of the first example ambient light energy harvesting diode illustrated in FIG. 2B when the light source is absence; and curve 614 represents a current-voltage relationship of the first example ambient light energy harvesting diode illustrated in FIG. 2B when the light source is presence. Also, curve 616 represents a power-voltage relationship of the first example ambient light energy harvesting diode illustrated in FIG. 2B when the light source is absence; and curve 618 represents a power-voltage relationship of the first example ambient light energy harvesting diode illustrated in FIG. 2B when the light source is presence. In this example, the first example ambient light energy harvesting diode may convert the ambient light to a peak output voltage of about 0.45 V with a peak output power of about 1.0 μW. In some aspects, the output current capability may be derivable based on the output voltage and the output power based on the Ohm's Law. In this example, the first example ambient light energy harvesting diode may have a maximum power density (the power generated versus area occupied) of about 1.5×10⁻⁴ W/mm².

As shown in FIG. 6B, curve 622 represents a current-voltage relationship of the second example ambient light energy harvesting diode illustrated in FIG. 3A when the light source is absence; and curve 624 represents a current-voltage relationship of the second example ambient light energy harvesting diode illustrated in FIG. 3A when the light source is presence. Also, curve 626 represents a power-voltage relationship of the second example ambient light energy harvesting diode illustrated in FIG. 3A when the light source is absence; and curve 628 represents a power-voltage relationship of the second example ambient light energy harvesting diode illustrated in FIG. 3A when the light source is presence. In this example, the second example ambient light energy harvesting diode may convert the ambient light to a peak output voltage similar to the peak output voltage shown in FIG. 6A with a peak output power about 1.5 to 1.7 times the peak output power shown in FIG. 6A. In this example, the second example ambient light energy harvesting diode may have a maximum power density (the power generated versus area occupied) about 1.5 to 1.7 times the maximum power density shown in FIG. 6A.

As shown in FIG. 6C, curve 632 represents a current-voltage relationship of the third example ambient light energy harvesting diode illustrated in FIG. 4A when the light source is absence; and curve 634 represents a current-voltage relationship of the third example ambient light energy harvesting diode illustrated in FIG. 4A when the light source is presence. Also, curve 636 represents a power-voltage relationship of the third example ambient light energy harvesting diode illustrated in FIG. 4A when the light source is absence; and curve 638 represents a power-voltage relationship of the third example ambient light energy harvesting diode illustrated in FIG. 4A when the light source is presence. In this example, the third example ambient light energy harvesting diode may convert the ambient light to a peak output voltage similar to the peak output voltage shown in FIG. 6A with a peak output power about 2.0 to 2.4 times the peak output power shown in FIG. 6A. In this example, the third example ambient light energy harvesting diode may have a maximum power density (the power generated versus area occupied) about 2.2 to 2.7 times the maximum power density shown in FIG. 6A.

As shown in FIG. 6D, curve 642 represents a current-voltage relationship of the fourth example ambient light energy harvesting diode illustrated in FIG. 5A when the light source is absence; and curve 644 represents a current-voltage relationship of the fourth example ambient light energy harvesting diode illustrated in FIG. 5A when the light source is presence. Also, curve 646 represents a power-voltage relationship of the fourth example ambient light energy harvesting diode illustrated in FIG. 5A when the light source is absence; and curve 648 represents a power-voltage relationship of the fourth example ambient light energy harvesting diode illustrated in FIG. 5A when the light source is presence. In this example, the fourth example ambient light energy harvesting diode may convert the ambient light to a peak output voltage similar to the peak output voltage shown in FIG. 6A with a peak output power about 1.2 to 1.5 times the peak output power shown in FIG. 6A. In this example, the fourth example ambient light energy harvesting diode may have a maximum power density (the power generated versus area occupied) about 1.7 to 2.1 times the maximum power density shown in FIG. 6A.

The curves shown in FIGS. 6A-6D are merely non-limiting examples, as the peak output voltage and the peak output power may vary as the dimensions of the doped regions, the number of the doped regions, the dopant concentrations, and/or the dopant material used. In some aspects, the configuration as illustrated by the third example ambient light energy harvesting diode (e.g., based on the semiconductor structure 410 in FIG. 4A) may tend to provide a greater peak output voltage and/or a greater peak output power than other configurations based on the other example ambient light energy harvesting diodes (e.g., based on the semiconductor structures 210, 310, and 510) with the same or similar device footprint (i.e., a greater power density). This may be because more vertical and/or lateral junctions may be defined based on the configuration as illustrated by the third example ambient light energy harvesting diode (e.g., based on the semiconductor structure 410 in FIG. 4A) than other examples.

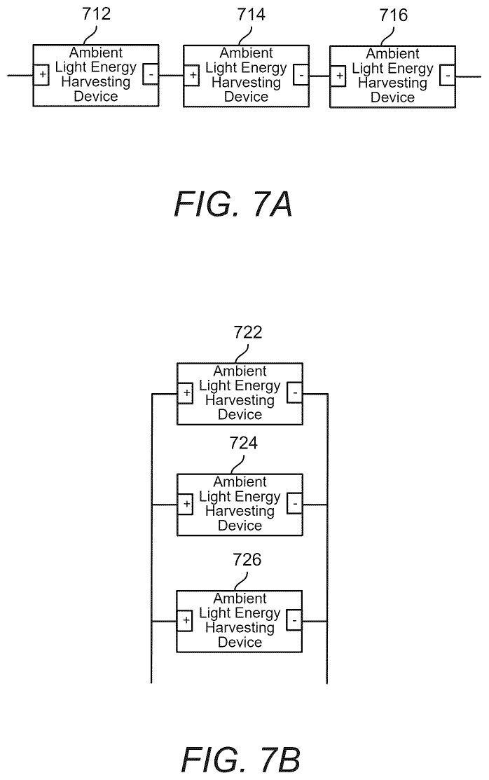

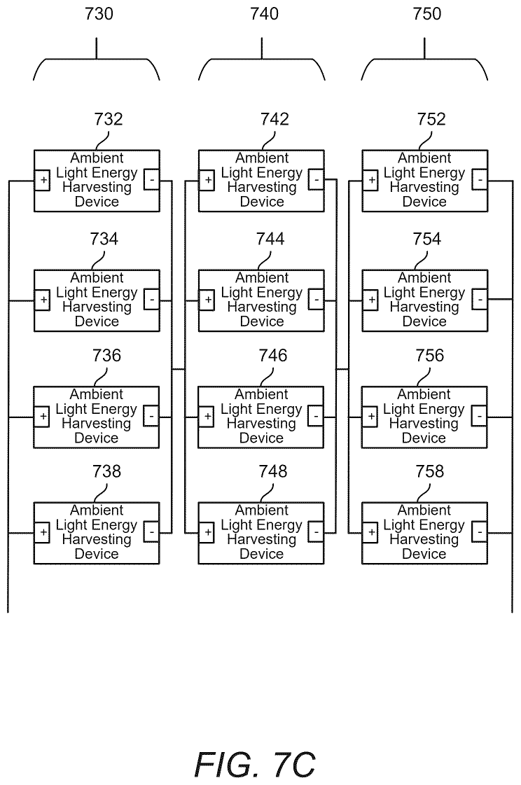

In some aspects, multiple ambient light energy harvesting devices, such as multiple ambient light energy harvesting devices based on the example structures illustrated in FIGS. 2A-5B, may be electrically coupled in series and/or in parallel in order to reach a higher peak output voltage and/or a higher peak output power for properly powering a corresponding processing circuitry. For example, FIGS. 7A-7C illustrate example configurations of ambient light energy harvesting devices, according to aspects of the disclosure.

As shown in FIG. 7A, multiple ambient light energy harvesting devices 712, 714, and 716 may be electrically coupled in series in order to reach a higher peak output voltage, which may be about the summation of the peak output voltages of the ambient light energy harvesting devices 712, 714, and 716 minus a voltage reduction due to losses.

As shown in FIG. 7B, multiple ambient light energy harvesting devices 722, 724, and 726 may be electrically coupled in parallel in order to reach a higher peak output power (or a higher peak output current), which may be about the summation of the peak output powers (or peak output currents) of the ambient light energy harvesting devices 722, 724, and 726 minus a power or current reduction due to losses.

As shown in FIG. 7C, multiple ambient light energy harvesting devices 732, 734, 736, and 738 may be electrically coupled in parallel to form a combination 730 in order to reach a higher peak output power as illustrated in FIG. 7B. Also, multiple ambient light energy harvesting devices 742, 744, 746, and 748 may be electrically coupled in parallel to form a combination 740; and multiple ambient light energy harvesting devices 752, 754, 756, and 758 may be electrically coupled in parallel to form a combination 750. Moreover, the combinations 730, 740, and 750 may be electrically coupled in series in order to reach a higher peak output voltage as illustrated in FIG. 7A.

In addition, similar to the configurations shown in FIGS. 7A-7C regarding connecting multiple ambient light energy harvesting devices, even within an ambient light energy harvesting device, the ambient light energy harvesting diodes thereof may be electrically connected in parallel or in series in order to reach a desirable peak output voltage and a desirable peak output power for the ambient light energy harvesting device.

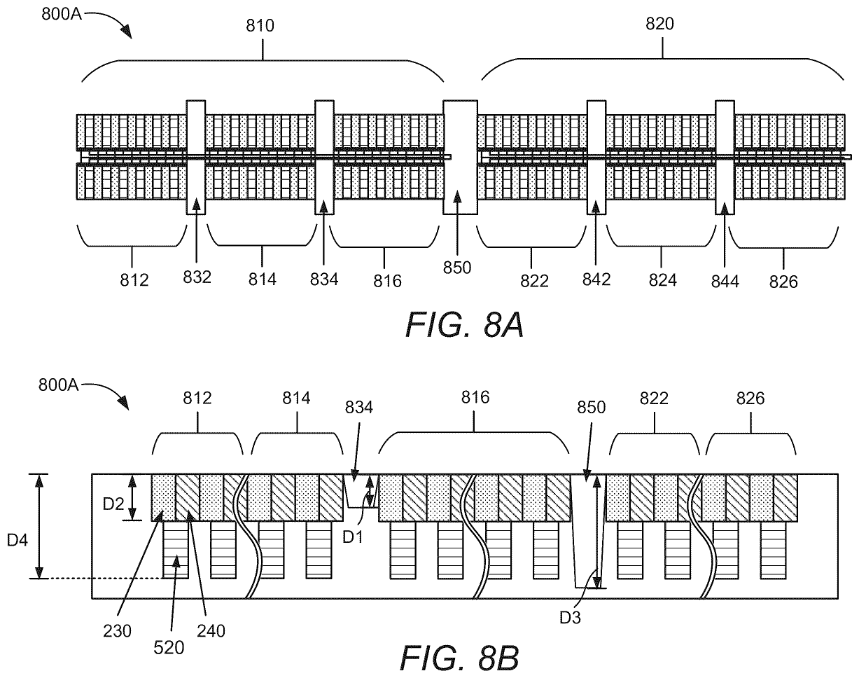

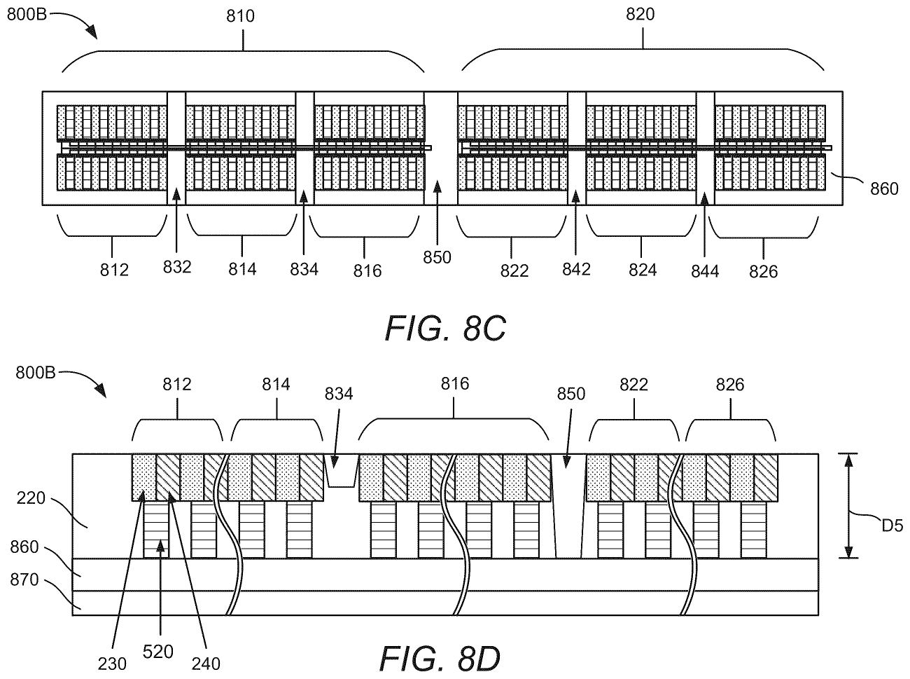

Moreover, FIGS. 8A-8D illustrate example isolation structures for one or more ambient light energy harvesting devices, according to aspects of the disclosure. The isolation structures shown in FIGS. 8A-8D may be implemented together with the semiconductor structure 510 as a non-limiting example, and certain details are not labeled or further described. In some aspects, the isolation structures illustrated in FIGS. 8A-8D may be implemented together with any of the semiconductor structures 210, 310, 410, or 510.

FIG. 8A illustrates a top view of a first example 800A including two ambient light energy harvesting devices 810 and 820, according to aspects of the disclosure. FIG. 8B illustrates a cross-sectional view of a portion of the first example 800A including the ambient light energy harvesting devices 810 and 820, according to aspects of the disclosure. As shown in FIG. 8A, the ambient light energy harvesting device 810 may include structure portions 812, 814, and 816 respectively corresponding to ambient light energy harvesting diodes that are electrically coupled together in series or in parallel. Each one of the structure portions 812, 814, and 816 may be similar to the semiconductor structure 510 as a non-limiting example. Also, the ambient light energy harvesting device 820 may include structure portions 822, 824, and 826 respectively corresponding to ambient light energy harvesting diodes that are electrically coupled together in series or in parallel. Each one of the structure portions 822, 824, and 826 may also be similar to the semiconductor structure 510 as a non-limiting example.

Moreover, an isolation structure 832 (e.g., a shallow trench isolation (STI) structure) may be disposed between the structure portion 812 and the structure portion 814; an isolation structure 834 (e.g., an STI structure) may be disposed between the structure portion 814 and the structure portion 816; an isolation structure 842 (e.g., an STI structure) may be disposed between the structure portion 822 and the structure portion 824; and an isolation structure 844 (e.g., an STI structure) may be disposed between the structure portion 824 and the structure portion 826. Also, an isolation structure 850 (e.g., a deep trench isolation (DTI) structure) may be disposed between the ambient light energy harvesting device 810 and the ambient light energy harvesting device 820, such as between the structure portion 816 defining a diode of the ambient light energy harvesting device 810 and the structure portion 822 defining a diode of the ambient light energy harvesting device 820. In some aspects, the isolation structure 850 may be disposed at an edge of the diode based on the structure portion 816, or at an edge of the diode based on the structure portion 822, or both.

As shown in FIG. 8B, in some aspects, the depth of the isolation structures 832, 834, 842, and 844 (e.g., the depth D1 of the isolation structure 834 in FIG. 8B) may be lower than a depth D2 of the doped regions (e.g., doped regions 230 and 240). In some aspects, the depth of the isolation structure 850 (e.g., the depth D3 in FIG. 8B) may be greater than a depth D4 of the buried doped structure (e.g., the buried doped structure 520). In some aspects, the depth D3 may range from 7 to 9 μm. In some aspects, the depth D3 may be at least 1 μm deeper than the depth D4.

FIG. 8C illustrates a top view of a second example 800B, and FIG. 8D illustrates a cross-sectional view of a portion of the second example 800B, according to aspects of the disclosure. The components in FIGS. 8C and 8D that are the same or similar to those in FIGS. 8A and 8B are given the same reference numbers, and detailed description thereof may be simplified or omitted.

As shown in FIGS. 8C and 8D, compared with the first example 800A, the second example 800B may further include a buried isolation layer 860 below the substrate portion 220. In some aspects, the buried isolation layer 860 may be disposed above a substrate 870. In some aspects, the buried isolation layer 860 may be a buried oxide layer. In some aspects, a depth D5 of an upper surface of the buried isolation layer 860 may range from 2 to 4 μm. According to the second example 800B, the depth of the isolation structure 850 may be the same as or greater than the depth of the buried doped structure (e.g., the buried doped structure 520).

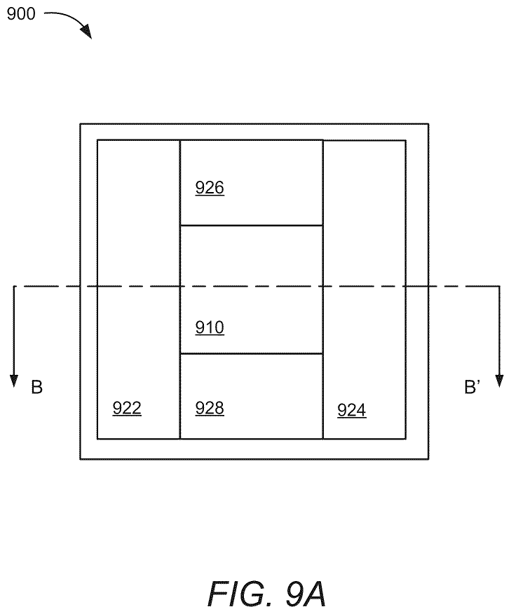

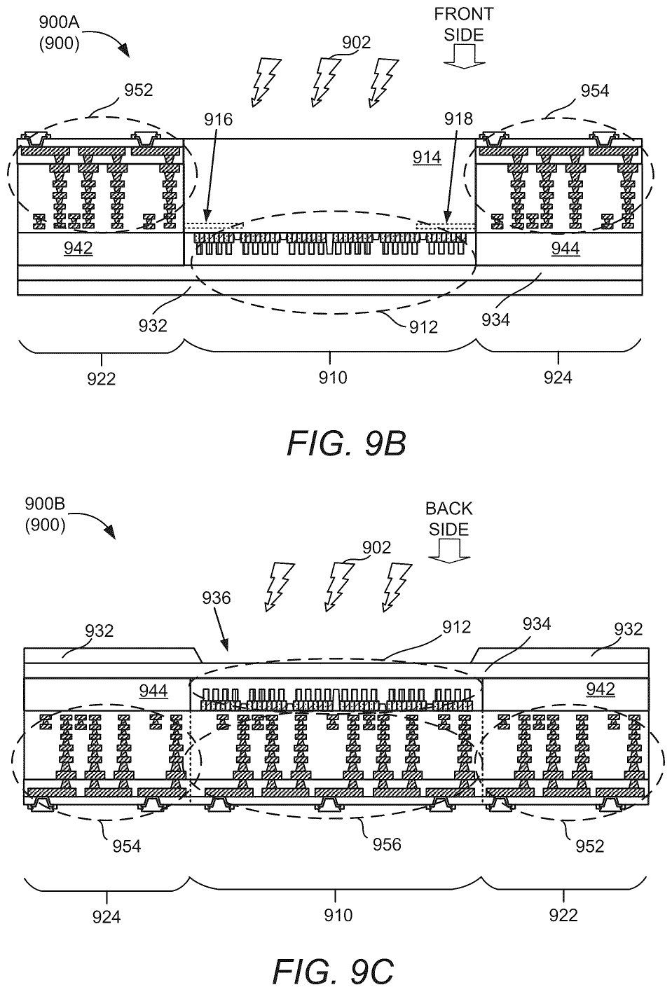

FIG. 9A is a simplified top view of an IC die 900 that incorporates an example ambient light energy harvesting device, according to aspects of the disclosure. In some aspects, the IC die 900 may correspond to the IC die 120 or the IC die 130. As shown in FIG. 9A, the IC die 900 may include a power supply portion 910 where an ambient light energy harvesting device (such as the ambient light energy harvesting device 106 in FIGS. 1B-1C and/or any of the examples illustrated in FIGS. 2A-8D) may be formed. In some aspects, the IC die 900 may include circuitry portions 922, 924, 926, and 928 where processing circuitry (such as the IoT processing circuitry 102 and/or the input and/or output interface 108 in FIGS. 1B-1C) may be formed.

In some aspects, the power supply portion 910 being placed in the center of the IC die 900 and surrounded by the circuitry portions 922, 924, 926, and 928 are merely depicted as a non-limiting example. In some aspects, the ambient light energy harvesting device of the IC die 900 may be configured to receive the ambient light based on different approaches, as further illustrated based on the cross-sectional views of the IC die 900 taken along the line B-B′ in FIG. 9A.

FIG. 9B is a simplified cross-sectional view of the IC die 900A, which may correspond to configuring the IC die 900 in FIG. 9A to receive the ambient light (e.g., the ambient light 902) based on a frontside illumination approach, according to aspects of the disclosure. The components in FIG. 9B that are the same or similar to those in FIG. 9A may be given the same reference numbers, and detail description thereof may be omitted.

As shown in FIG. 9B, the IC die 900A may include in the power supply portion 910 an ambient light energy harvesting device 912. In this non-limiting example, the ambient light energy harvesting device 912 may be based on the semiconductor structure 510 in FIG. 5A and the isolation structures in FIG. 8D. In some aspects, the ambient light energy harvesting device 912 may be based on any of the examples, individually or in combination, as illustrated in FIGS. 2A-8D.

As shown in FIG. 9B, the IC die 900A may include a substrate 932 and a buried isolation layer 934 on the substrate 932. In some aspects in the circuitry portion 922, the IC die 900A may include a first front-end-of-line (FEOL) portion 942 on the buried isolation layer 934, and a first metallization portion 952 on the first FEOL portion 942. In some aspects in the circuitry portion 924, the IC die 900A may include a second FEOL portion 944 on the buried isolation layer 934, and a second metallization portion 954 on the first FEOL portion 942. In some aspects, the FEOL portions 942 and 944 may include electrical components and local conductive paths configured as various circuit blocks. In some aspects, the first and second metallization portions 952 and 954 may include layers of conductive traces and vias configured to connect the circuit blocks into corresponding functional devices, to provide a power distribution network (PDN) to the functional devices, and to provide terminal structures to be coupled to external components (e.g., a printed circuit board). In some aspects, the first and second metallization portions 952 and 954 may include copper traces and vias embedded in a dielectric material.

In some aspects in the power supply portion 910, the IC die 900A may include a dielectric portion 914 on the ambient light energy harvesting device 912 and may include conductive structures 916 and 918 electrically connecting the diodes of the ambient light energy harvesting device 912 and/or electrically connecting the ambient light energy harvesting device 912 to any of all of the circuitry portions 922, 924, 926, and 928. In some aspects, the conductive structures 916 and 918 may be formed as an extension of one or more lower conductive trace and/or via layers of the first and second metallization portions 952 and 954. In some aspects, the dielectric portion 914 may include a dielectric material, such as SiO₂ and/or fluorosilicate glass (FSG), that may allow the ambient light 902 to reach the diodes of the ambient light energy harvesting device 912 from a front side (the direction labeled as “FRONT SIDE” in FIG. 9B) of the IC die 900A.

FIG. 9C is a simplified cross-sectional view of the IC die 900B, which may correspond to configuring the IC die 900 in FIG. 9A to receive the ambient light (e.g., the ambient light 902) based on a backside illumination approach, according to aspects of the disclosure. The components in FIG. 9C that are the same or similar to those in FIGS. 9A and 9B may be given the same reference numbers, and detail description thereof may be omitted.

Compared with the IC die 900A in FIG. 9B, the IC die 900B is depicted in an upside-down position, where a portion of the substrate 932 may be removed (e.g., by an etching process) to define an opening 936. In some aspects in the power supply portion 910 in place of the dielectric portion 914, the IC die 900B may include a third metallization portion 956 that may be formed integrally with the first and second metallization portions 952 and 954. In some aspects, the buried isolation layer 934 may include a dielectric material, such as SiO₂ and/or FSG, that may allow the ambient light 902 to reach the diodes of the ambient light energy harvesting device 912 from the back side (the direction labeled as “BACK SIDE” in FIG. 9C) of the IC die 900B.

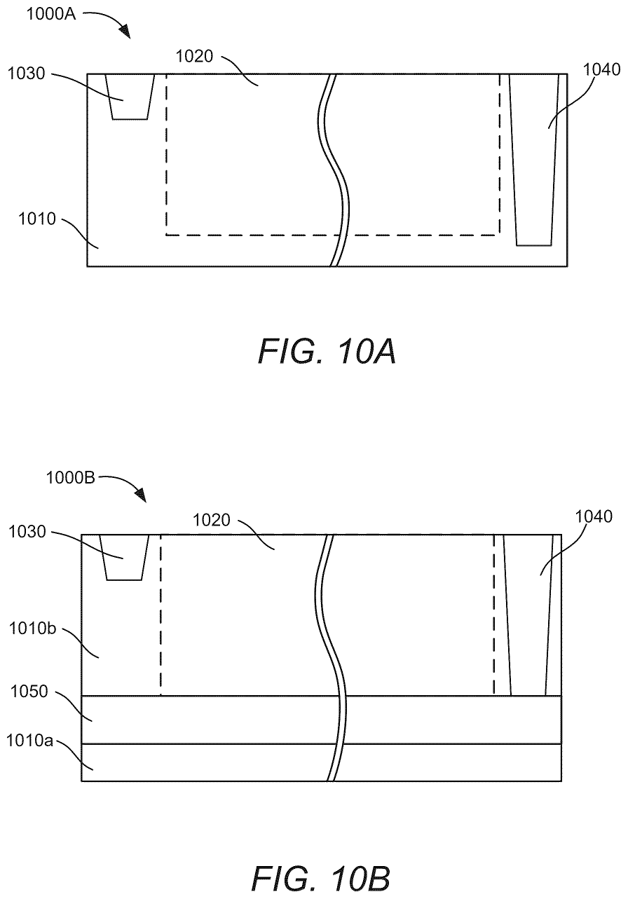

In some aspects, any of the semiconductor structures 210, 310, 410, or 510 may be formed together with any combination of the isolation structures 832, 834, 842, and/or 844, the isolation structure 850, and/or the buried isolation layer 860 illustrated in FIGS. 8A-8D. FIGS. 10A and 10B illustrate example semiconductor structures with isolation structure from which an ambient light energy harvesting device may be formed, according to aspects of the disclosure.

As shown in FIG. 10A, a first example semiconductor structure 1000A may include a substrate 1010 and a device region 1020 in which one or more diodes based on any one or combinations of the semiconductor structures 210, 310, 410, or 510 may be formed. In some aspects, the substrate portion 220 of the semiconductor structures 210, 310, 410, or 510 may be based on the substrate 1010.

Also, the first example semiconductor structure 1000A may further include an isolation structure 1030, an isolation structure 1040, or both formed in the substrate 1010. In some aspects, the isolation structure 1030 may correspond to any of the isolation structures 832, 834, 842, and/or 844 and may be an STI structure. In some aspects, the isolation structure 1040 may correspond to the isolation structure 850 and may be a DTI structure. In some aspects, the isolation structure 1030 and/or the isolation structure 1040 may be formed prior to or after the one or more diodes are formed in the device region 1020.

In some aspects, the depth of the isolation structure 1030 may be configured to be lower than the depth of the doped regions (e.g., doped regions 230 and 240) to be formed in the device region 1020. In some aspects, the depth of the isolation structure 1040 may be configured to be at least 1 μm deeper than the depth of a buried doped structure (e.g., the buried doped structure 270, 420, or 520) to be formed in the device region 1020. In some aspects, the depth of the buried doped structure may range from 7 to 9 μm.

In some aspects, the isolation structure 1030 and/or the isolation structure 1040 may be formed based on performing an etching process to form one or more openings (i.e., trenches) I the substrate 1010, and then filling the openings with an isolation material to form the isolation structure 1030 and/or the isolation structure 1040. In some aspects, filling the openings with an isolation material may include filing the one or more openings based on a deposition process (e.g., a chemical vapor deposition (CVD) process) and then polishing an upper portion of the deposited isolation material based on a polishing process (e.g., a chemical mechanical polishing (CMP) process).

In some aspects, the substrate 1010 may include silicon, and the isolation material may include silicon oxide.

As shown in FIG. 10B, a second example semiconductor structure 1000B may include a first substrate 1010a, a second substrate 1010b, an isolation structure 1050 between the first substrate 1010a and the second substrate 1010b, and a device region 1020 in which one or more diodes based on any one or combinations of the semiconductor structures 210, 310, 410, or 510 may be formed. In some aspects, the substrate portion 220 of the semiconductor structures 210, 310, 410, or 510 may be based on the second substrate 1010a.

In some aspects, compared with the first example semiconductor structure 1000A, the second example semiconductor structure 1000B may include the isolation structure 1050 that may correspond to the buried isolation layer 860 and may be a buried oxide layer. In some aspects, the isolation structure 1050 may be formed prior to formation of the isolation structure 1030, the isolation structure 1040, and any components in the device region 1020. In some aspects, the isolation structure 1050 (e.g., a buried isolation layer) may be formed based on performing an oxygen implantation followed by an oxidation process on a substrate or based on a wafer bonding process by bonding multiple substrates (e.g., bonding the first substrate 1010a with the second substrate 1010b that already has the isolation structure 1050 formed thereon by a surface oxidation process). In some aspects, the isolation structure 1030 and/or the isolation structure 1040 may be formed prior to or after the one or more diodes are formed in the device region 1020.

In some aspects, the substrate 1010a and the substrate 1010b may include silicon, the isolation material may include silicon oxide, and the isolation structure 1050 may include silicon oxide.

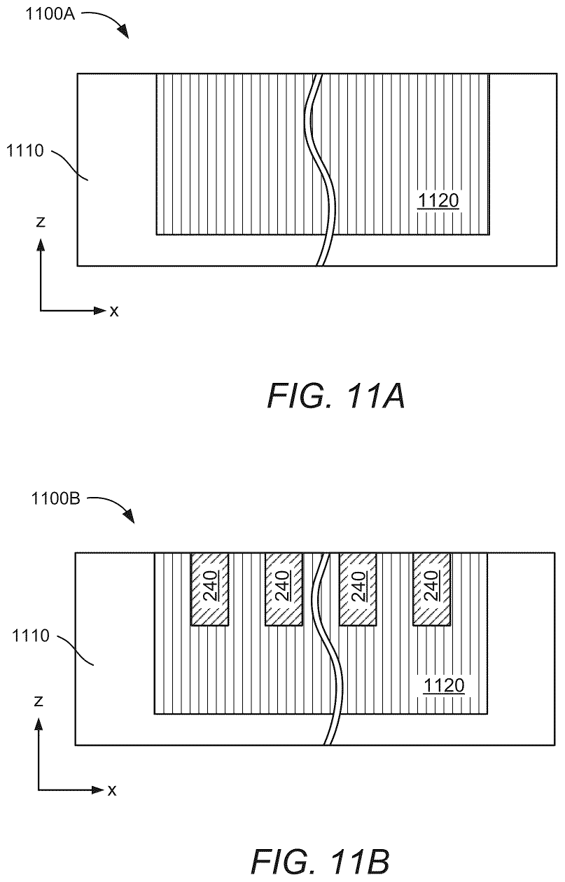

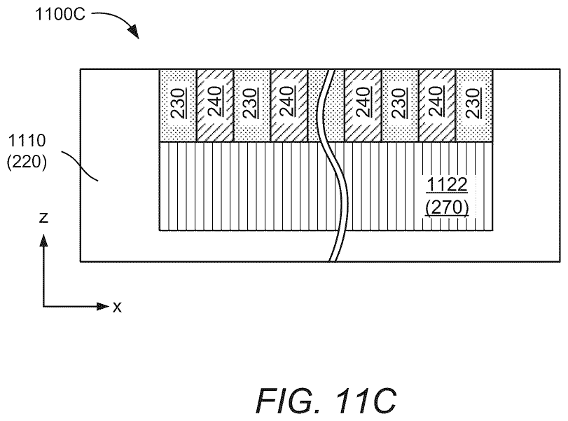

FIGS. 11A-11C illustrate structures at various stages of manufacturing a semiconductor structure, such as the semiconductor structure 210 in FIG. 2B as a non-limiting example, for an ambient light energy harvesting device, according to aspects of the disclosure. The components illustrated in FIGS. 11A-11C that are the same or similar to those of FIG. 2B are given the same reference numbers, and the detailed description thereof may be omitted.

As shown in FIG. 11A, a structure 1100A may be formed by forming in a substrate 1110 a buried doped structure 1120. In some aspects, the structure 1100A may have isolation structures already formed based on the structure 1000A, and the substrate 1110 may correspond to the substrate 1010. In some aspects, the structure 1100A may have isolation structures already formed based on the structure 1000B, and the substrate 1110 may correspond to the substrate 1010b. In some aspects, the structure 1100A may not have any isolation structures yet.

In some aspects, the substrate 1110 may include silicon with a dopant concentration ranging from 10×10¹² cm⁻³ to 10×10¹⁴ cm⁻³. In some aspects, the substrate 1110 may be doped based on a first doping type, and the buried doped structure 1120 may be doped based on a second doping type. In some aspects, one of the first doping type and the second doping type may be a p-doping type based on dopants that comprise As, P, Sb, or a combination thereof. In some aspects, the other one of the first doping type and the second doping type may be an n-doping type based on dopants that comprise B, BF₂, In, or a combination thereof.

As shown in FIG. 11B, a structure 1100B may be formed based on the structure 1100A by forming doped regions 240 in the buried doped structure 1120. In some aspects, the doped regions 240 may be doped based on the second doping type as discussed above.

As shown in FIG. 11C, a structure 1100C may be formed based on the structure 1100B by forming doped regions 230 in the buried doped structure 1120. In some aspects, the doped regions 230 may be doped based on the first doping type as discussed above. In some aspects, the structure 1100C may correspond to the structure 210 in FIG. 2B, where at least a portion of the substrate 1110 may correspond to the substrate portion 220, and the remaining portion 1122 of the buried doped structure 1120 that is not converted into the doped regions 230 and 240 may correspond to the buried doped structure 270. As illustrated in FIGS. 2B and 2C, various p-n junctions (e.g., lateral p-n junctions 282 and 286 and vertical p-n junctions 284 and 288) of an ambient light energy harvesting diode may be defined among the doped regions 230 and 240, the buried doped structure 270, and the substrate portion 220.

In some aspects, while FIGS. 11B and 11C show that the doped regions 230 are formed after the doped regions 240, the doped regions 230 may be formed before the doped regions 240.

Afterwards, conductive structures (e.g., the first conductive structure 250 and/or the second conductive structure 260) may be formed over the structure 1100C that may be electrically coupled to the doped regions 230 and/or the doped regions 240.

In some aspects, a thickness of the doped regions 230 and 240 (measurable along a vertical direction, such as the z direction) may range from 0.2 to 0.4 μm. In some aspects, a thickness of the buried doped structure 270 (measurable along the vertical direction, such as the z direction) may range from 0.4 to 0.6 μm.

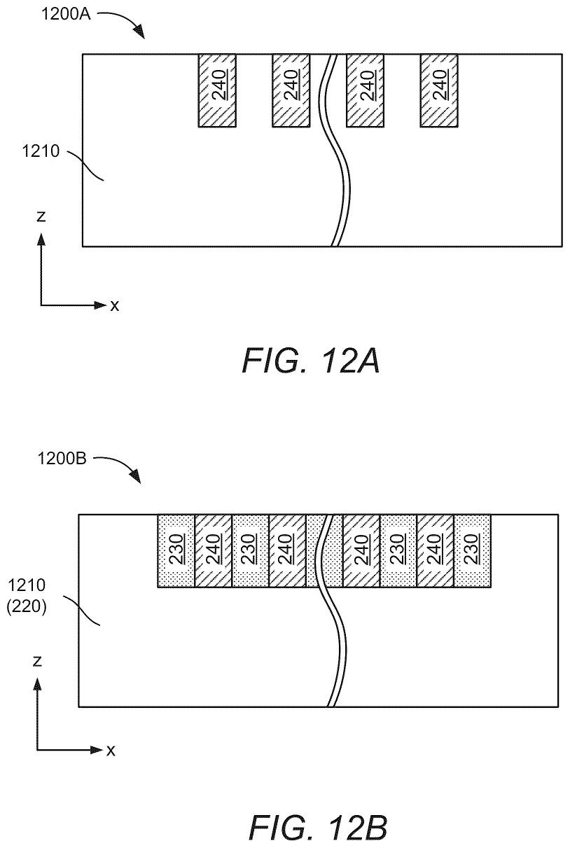

FIGS. 12A-12B illustrate structures at various stages of manufacturing a semiconductor structure, such as the semiconductor structure 310 in FIG. 3A as a non-limiting example, for an ambient light energy harvesting device, according to aspects of the disclosure. The components illustrated in FIGS. 12A-12B that are the same or similar to those of FIG. 3A are given the same reference numbers, and the detailed description thereof may be omitted.

As shown in FIG. 12A, a structure 1200A may be formed based on forming doped regions 240 in a substrate 1210. In some aspects, the structure 1200A may have isolation structures already formed based on the structure 1000A, and the substrate 1210 may correspond to the substrate 1010. In some aspects, the structure 1200A may have isolation structures already formed based on the structure 1000B, and the substrate 1210 may correspond to the substrate 1010b. In some aspects, the structure 1200A may not have any isolation structures yet.

In some aspects, the substrate 1210 may include silicon with a dopant concentration ranging from 10×10¹² cm⁻³ to 10×10¹⁴ cm⁻³. In some aspects, the substrate 1210 may be doped based on a first doping type. In some aspects, the doped regions 240 may be doped based on the second doping type as discussed above. In some aspects, one of the first doping type and the second doping type may be a p-doping type based on dopants that comprise As, P, Sb, or a combination thereof. In some aspects, the other one of the first doping type and the second doping type is an n-doping type based on dopants that comprise B, BF₂, In, or a combination thereof.

As shown in FIG. 12B, a structure 1200B may be formed based on the structure 1200A by forming doped regions 230 in the substrate 1210. In some aspects, the doped regions 230 may be doped based on the first doping type as discussed above. In some aspects, the structure 1200B may correspond to the structure 310 in FIG. 3A, where at least a portion of the substrate 1210 may correspond to the substrate portion 220. As illustrated in FIGS. 3A and 3B, various p-n junctions (e.g., lateral p-n junctions 282 and vertical p-n junctions 322) of an ambient light energy harvesting diode may be defined among the doped regions 230 and 240, and the substrate portion 220.

In some aspects, while FIGS. 12A and 12B show that the doped regions 230 are formed after the doped regions 240, the doped regions 230 may be formed before the doped regions 240.

Afterwards, conductive structures (e.g., the first conductive structure 250 and/or the second conductive structure 260) may be formed over the structure 1200B that may be electrically coupled to the doped regions 230 and/or the doped regions 240.

In some aspects, a thickness of the doped regions 230 and 240 (measurable along a vertical direction, such as the z direction) may range from 0.4 to 0.8 μm.

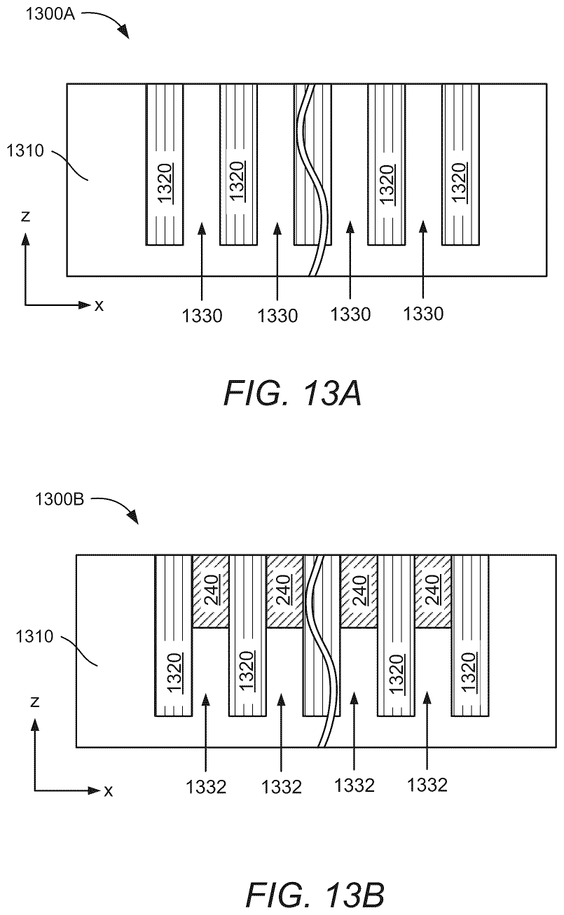

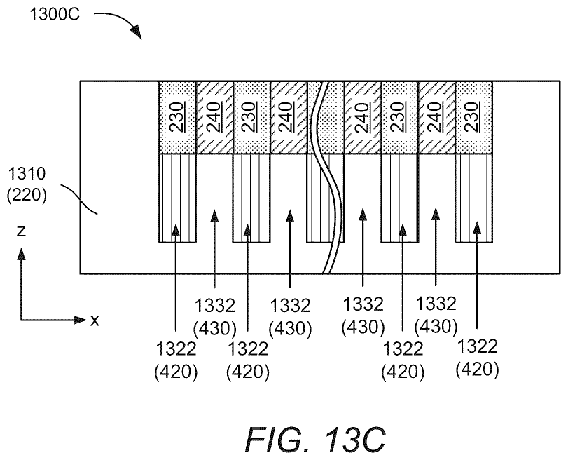

FIGS. 13A-13C illustrate structures at various stages of manufacturing a semiconductor structure, such as the semiconductor structure 410 in FIG. 4A as a non-limiting example, for an ambient light energy harvesting device, according to aspects of the disclosure. The components illustrated in FIGS. 13A-13C that are the same or similar to those of FIG. 4A are given the same reference numbers, and the detailed description thereof may be omitted.

As shown in FIG. 13A, a structure 1300A may be formed by forming in a substrate 1310 a buried doped structure 1320. In some aspects, the buried doped structure 1320 may include a plurality of buried doped fingers defining a portion of the substrate 1310 among the buried doped fingers as a plurality of substrate fingers 1330. In some aspects, the structure 1300A may have isolation structures already formed based on the structure 1000A, and the substrate 1310 may correspond to the substrate 1010. In some aspects, the structure 1300A may have isolation structures already formed based on the structure 1000B, and the substrate 1310 may correspond to the substrate 1010b. In some aspects, the structure 1300A may not have any isolation structures yet.

In some aspects, the substrate 1310 may include silicon with a dopant concentration ranging from 10×10¹² cm⁻³ to 10×10¹⁴ cm⁻³. In some aspects, the substrate 1310 may be doped based on a first doping type, and the buried doped structure 1320 may be doped based on a second doping type. In some aspects, one of the first doping type and the second doping type may be a p-doping type based on dopants that comprise As, P, Sb, or a combination thereof. In some aspects, the other one of the first doping type and the second doping type is an n-doping type based on dopants that comprise B, BF₂, In, or a combination thereof.

As shown in FIG. 13B, a structure 1300B may be formed based on the structure 1300A by forming doped regions 240 in the substrate fingers 1330. In some aspects, the doped regions 240 may be doped based on the second doping type as discussed above. The remaining portion of the substrate fingers 1330 that is not part of the doped regions 240 may constitute the remaining substrate fingers 1332.

As shown in FIG. 13C, a structure 1300C may be formed based on the structure 1300B by forming doped regions 230 in the buried doped structure 1320. In some aspects, the doped regions 230 may be doped based on the first doping type as discussed above. The remaining portion of the buried doped structure 1320 that is not part of the doped regions 230 may constitute the remining buried doped structure 1322.

In some aspects, the structure 1300C may correspond to the structure 410 in FIG. 4A, where at least a portion of the substrate 1310 may correspond to the substrate portion 220, the remaining buried doped structure 1322 may correspond to the buried doped structure 420, and the remaining substrate fingers 1332 may correspond to the substrate fingers 430. As illustrated in FIGS. 4A and 4B, various p-n junctions (e.g., lateral p-n junctions 282 and 436 and vertical p-n junctions 432, 434, and 438) of an ambient light energy harvesting diode may be defined among the doped regions 230 and 240, the buried doped structure 420, and the substrate portion 220 (including the substrate fingers 430).

In some aspects, while FIGS. 13A and 13B show that the doped regions 230 are formed after the doped regions 240, the doped regions 230 may be formed before the doped regions 240.

Afterwards, conductive structures (e.g., the first conductive structure 250 and/or the second conductive structure 260) may be formed over the structure 1300C that may be electrically coupled to the doped regions 230 and/or the doped regions 240.

In some aspects, a thickness of the doped regions 230 and 240 (measurable along a vertical direction, such as the z direction) may range from 0.2 to 0.4 μm. In some aspects, a thickness of the buried doped structure 420 (measurable along the vertical direction, such as the z direction) may range from 0.4 to 0.6 μm.

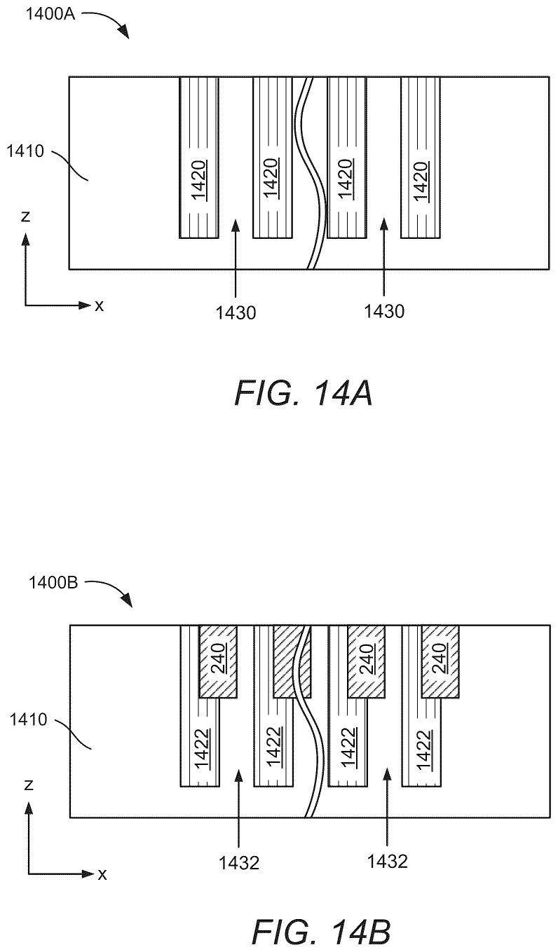

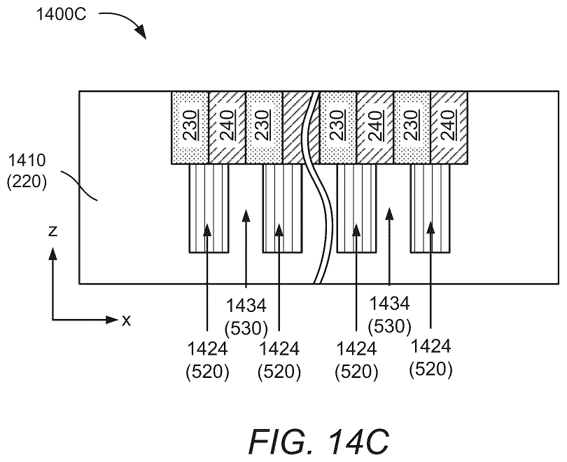

FIGS. 14A-14C illustrate structures at various stages of manufacturing a semiconductor structure, such as the semiconductor structure 510 in FIG. 5A as a non-limiting example, for an ambient light energy harvesting device, according to aspects of the disclosure. The components illustrated in FIGS. 14A-14C that are the same or similar to those of FIG. 5A are given the same reference numbers, and the detailed description thereof may be omitted.

As shown in FIG. 14A, a structure 1400A may be formed by forming in a substrate 1410 a buried doped structure 1420. In some aspects, the buried doped structure 1420 may include a plurality of buried doped fingers defining a portion of the substrate 1410 among the buried doped fingers as a plurality of substrate fingers 1430. In some aspects, the structure 1400A may have isolation structures already formed based on the structure 1000A, and the substrate 1410 may correspond to the substrate 1010. In some aspects, the structure 1400A may have isolation structures already formed based on the structure 1000B, and the substrate 1410 may correspond to the substrate 1010b. In some aspects, the structure 1400A may not have any isolation structures yet.

In some aspects, the substrate 1410 may include silicon with a dopant concentration ranging from 10×10¹² cm⁻³ to 10×10¹⁴ cm⁻³. In some aspects, the substrate 1410 may be doped based on a first doping type, and the buried doped structure 1420 may be doped based on a second doping type. In some aspects, one of the first doping type and the second doping type may be a p-doping type based on dopants that comprise As, P, Sb, or a combination thereof. In some aspects, the other one of the first doping type and the second doping type is an n-doping type based on dopants that comprise B, BF₂, In, or a combination thereof.

As shown in FIG. 14B, a structure 1400B may be formed based on the structure 1400A by forming doped regions 240 in a portion of the buried doped structure 1420 and a portion the substrate fingers 1330. In some aspects, the doped regions 240 may be doped based on the second doping type as discussed above. The remaining portion of the buried doped structure 1420 that is not part of the doped regions 240 may constitute the remining buried doped structure 1422. Also, the remaining portion of the substrate fingers 1430 that is not part of the doped regions 240 may constitute the remining substrate fingers 1432.

As shown in FIG. 14C, a structure 1400C may be formed based on the structure 1400B by forming doped regions 230 in a portion of the remaining buried doped structure 1422 and a portion of the remaining the substrate fingers 1332. In some aspects, the doped regions 230 may be doped based on the first doping type as discussed above. The remaining portion of the buried doped structure 1422 that is not part of the doped regions 230 (and not part of the doped region 240) may constitute the remining buried doped structure 1424. Also, the remaining portion of the substrate fingers 1432 that is not part of the doped regions 240 (and not part of the doped region 240) may constitute the remining substrate fingers 1434.

In some aspects, the structure 1400C may correspond to the structure 510 in FIG. 5A, where at least a portion of the substrate 1410 may correspond to the substrate portion 220, the remaining buried doped structure 1424 may correspond to the buried doped structure 520, and the remaining substrate fingers 1434 may correspond to the substrate fingers 530. As illustrated in FIGS. 5A and 5B, various p-n junctions (e.g., lateral p-n junctions 282 and 536 and vertical p-n junctions 532, 534, and 538) of an ambient light energy harvesting diode may be defined among the doped regions 230 and 240, the buried doped structure 520, and the substrate portion 220 (including the substrate fingers 530).

In some aspects, while FIGS. 14A and 14B show that the doped regions 230 are formed after the doped regions 240, the doped regions 230 may be formed before the doped regions 240.

Afterwards, conductive structures (e.g., the first conductive structure 250 and/or the second conductive structure 260) may be formed over the structure 1400C that may be electrically coupled to the doped regions 230 and/or the doped regions 240.

In some aspects, a thickness of the doped regions 230 and 240 (measurable along a vertical direction, such as the z direction) may range from 0.2 to 0.4 μm. In some aspects, a thickness of the buried doped structure 420 (measurable along the vertical direction, such as the z direction) may range from 0.4 to 0.6 μm.

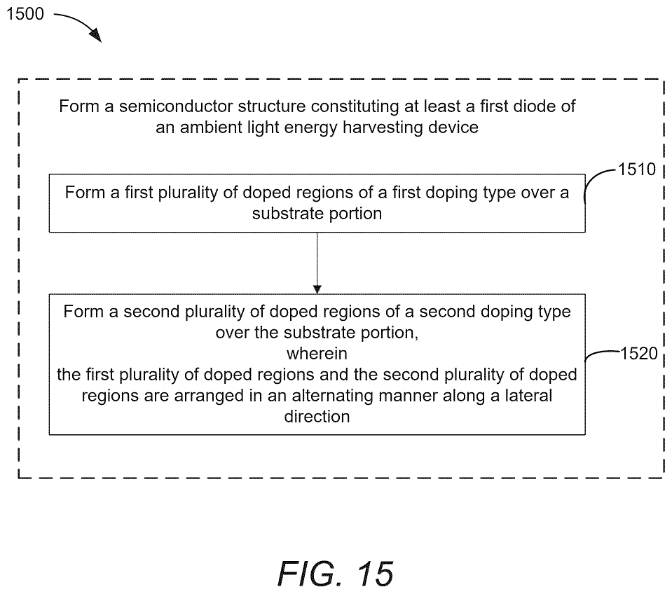

FIG. 15 illustrates a method 1500 for manufacturing an ambient light energy harvesting device (e.g., an ambient light energy harvesting device based on a semiconductor structure 210, 310, 410, and/or 510), according to aspects of the disclosure. In some aspects, FIGS. 10A-14C may depict the semiconductor structure at different stages of manufacturing (and for different structural variations) according to the method 1500. In some aspects, the method 1500 illustrate forming a first semiconductor structure (e.g., any of the semiconductor structure 210, 310, 410, and/or 510) constituting at least a first diode of the ambient light energy harvesting device. In some aspects, one or more additional diodes may be formed according to the method 1500.

At operation 1510, a first plurality of doped regions (e.g., the doped regions 230) of a first doping type may be formed over a substrate portion (e.g., the substrate portion 220).

At operation 1520, a second plurality of doped regions (e.g., the doped regions 240) of a first doping type may be formed over the substrate portion.

In some aspects, the first plurality of doped regions and the second plurality of doped regions may be arranged in an alternating manner along a lateral direction and configured to define lateral p-n junctions of the first diode between the first plurality of doped regions and the second plurality of doped regions. In some aspects, based on lower surfaces of the first plurality of doped regions and lower surfaces of the second plurality of doped regions being in contact with the substrate portion, the second plurality of doped regions and the substrate portion may further define first vertical p-n junctions of the first diode between the second plurality of doped regions and the substrate portion. In some aspects, based on a buried doped structure (e.g., the buried doped structure 270, 420, or 520) of the second doping type being formed under and in contact with at least a portion of the lower surfaces of the first plurality of doped regions, the first plurality of doped regions and the buried doped structure may further define second vertical p-n junctions of the first diode between the first plurality of doped regions and the buried doped structure.

In some aspects, a thickness of the first plurality of doped regions and the second plurality of doped regions may range from 0.2 to 0.4 μm, and a thickness of the buried doped structure may range from 0.4 to 0.6 μm. In some aspects, an entirety of the lower surfaces of the first plurality of doped regions and the lower surfaces of the second plurality of doped regions are in contact with the substrate portion, and a thickness of the first plurality of doped regions and the second plurality of doped regions may range from 0.4 to 0.8 μm.

In some aspects, the method 1500 may include forming the buried doped structure prior to the forming the first plurality of doped regions and prior to the forming the second plurality of doped regions. In some aspects, the buried doped structure may correspond to a buried doped layer on and in contact with the substrate portion, and the first plurality of doped regions and the second plurality of doped regions are on and in contact with the buried doped layer (e.g., the semiconductor structure 210 in FIG. 2A). In some aspects, the buried doped structure may correspond to a plurality of buried doped fingers on and in contact with the substrate portion, the substrate portion may include a plurality of substrate fingers, and the plurality of buried doped fingers and the plurality of substrate fingers may be arranged in an alternating manner along the lateral direction.

In some aspects as shown in FIG. 4A, each one of the lower surfaces of the first plurality of doped regions may be in contact with a respective one of the plurality of buried doped fingers, and each one of the lower surfaces of the second plurality of doped regions may be in contact with the substrate portion. In some aspects as shown in FIG. 5A, each one of the lower surfaces of the first plurality of doped regions may be in contact with a first respective portion of the plurality of buried doped fingers and a first respective portion of the plurality of substrate fingers, and each one of the lower surfaces of the second plurality of doped regions may be in contact with a second respective portion of the plurality of buried doped fingers and a second respective portion of the plurality of substrate fingers.

In some aspects, the first doping type may be a p-doping type, and the second doping type may be an n-doping type. In some aspects, the first doping type may be the n-doping type, and the second doping type may be the p-doping type. In some aspects, the substrate portion may include silicon with a dopant concentration ranging from 10×10² cm⁻³ to 10×10¹⁴ cm⁻³. In some aspects, one of the first doping type and the second doping type may be the p-doping type based on dopants that comprise As, P, Sb, or a combination thereof, and. In some aspects, the other one of the first doping type and the second doping type may be the n-doping type based on dopants that comprise B, boron BF₂, In, or a combination thereof.

After the operation 1520, in some aspects, a first conductive structure (e.g., the conductive structure 250) may be formed and may be electrically coupled to the first plurality of doped regions; and a second conductive structure (e.g., the conductive structure 260) may be formed and may be electrically coupled to the second plurality of doped regions.

In some aspects, the method 1500 may further include forming a deep trench isolation structure (e.g., the isolation structure 850) at an edge of the first diode, between the first diode of the ambient light energy harvesting device and a second diode of another ambient light energy harvesting device. In some aspects, a depth of the deep trench isolation structure may be at least 1 μm deeper than the buried doped structure. In some aspects, the method 1500 may further include forming a buried isolation layer (e.g., the buried isolation layer 860) below the substrate portion. In some aspects, a depth of an upper surface of the buried isolation layer ranges from 2 to 4 micrometers μm.

A technical advantage of the method 1500 corresponds to manufacturing an ambient light energy harvesting device in an IC die of an IoT device, where the ambient light energy harvesting device may include doped regions, substrate portion, and/or buried doped structures defining lateral p-n junctions and vertical p-n junctions at various depths. Accordingly, the resulting ambient light energy harvesting device may be configured to be responsive to a wide range of wavelengths of light. Also, the combination of all the lateral p-n junctions and vertical p-n junctions may enhance the light sensitivity of a diode of the ambient light energy harvesting device by 10 times or more compared with a diode in the same footprint with only vertical p-n junctions.

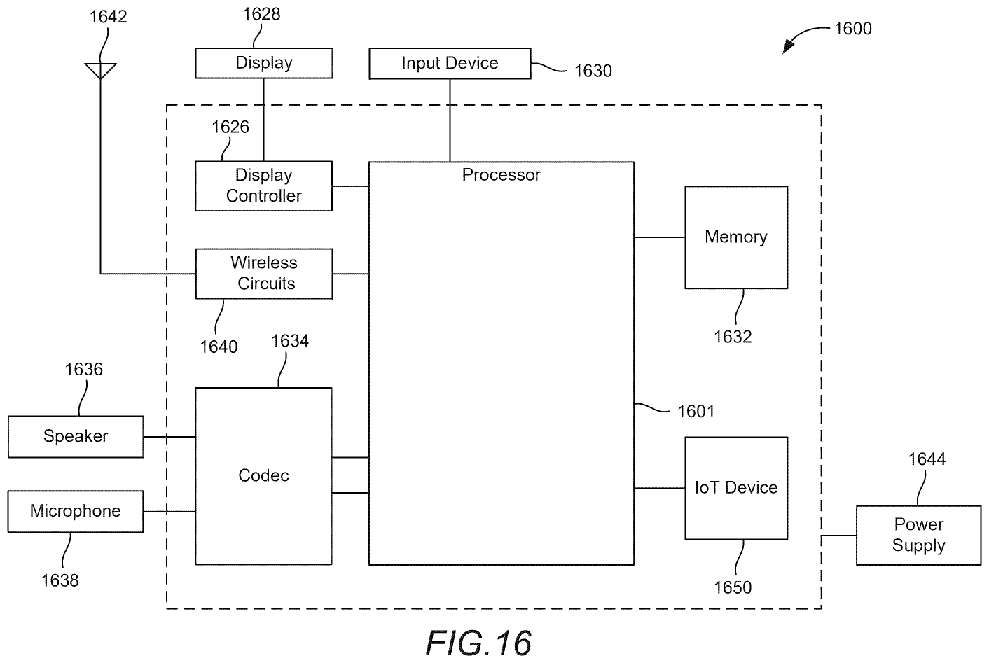

FIG. 16 illustrates a mobile device 1600, according to aspects of the disclosure. In some aspects, the mobile device 1600 may be implemented by including one or more IC dies including the ambient light energy harvesting device as disclosed herein.

In some aspects, mobile device 1600 may be configured as a wireless communication device. As shown, mobile device 1600 includes processor 1601. Processor 1601 may be communicatively coupled to memory 1632 over a link, which may be a die-to-die or chip-to-chip link. Mobile device 1600 also includes display 1628 and display controller 1626, with display controller 1626 coupled to processor 1601 and to display 1628. The mobile device 1600 may include input device 1630 (e.g., physical, or virtual keyboard), power supply 1644 (e.g., battery), speaker 1636, microphone 1638, and wireless antenna 1642. In some aspects, the power supply 1644 may directly or indirectly provide the supply voltage for operating some or all of the components of the mobile device 1600.

In some aspects, FIG. 16 may include coder/decoder (CODEC) 1634 (e.g., an audio and/or voice CODEC) coupled to processor 1601; speaker 1636 and microphone 1638 coupled to CODEC 1634; and wireless circuits 1640 (which may include a modem, RF circuitry, filters, etc.) coupled to wireless antenna 1642 and to processor 1601.

In some aspects, the mobile device 1600 may further include an IoT device 1650 that includes an IC die incorporating an ambient light energy harvesting device according to the various aspects described in this disclosure.

It should be noted that although FIG. 16 depicts a mobile device 1600, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

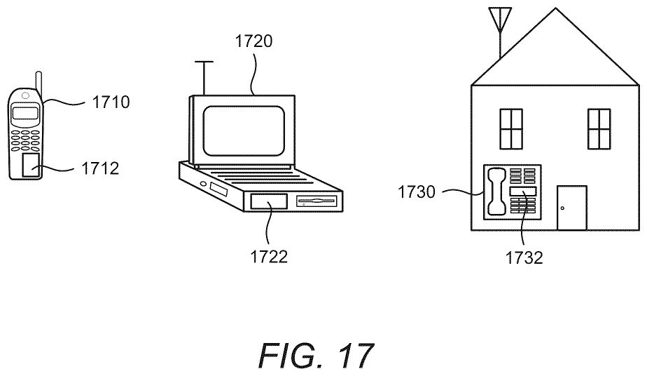

FIG. 17 illustrates various electronic devices 1710, 1720, and 1730 that may incorporate IC dies 1712, 1722, and 1732, which may be IoT devices with ambient light energy harvesting devices included therein, according to aspects of the disclosure.

For example, a mobile phone device 1710, a laptop computer device 1720, and a fixed location terminal device 1730 may each be considered generally user equipment (UE) and may include one or more IoT devices, such as IC dies 1712, 1722, and 1732. The IC dies 1712, 1722, and 1732 may be, for example, correspond to an IoT device having an ambient light energy harvesting device based on the examples described above with reference to FIGS. 2A-14C.

The devices 1710, 1720, and 1730 illustrated in FIG. 17 are merely non-limiting examples. Other electronic devices may also feature the IoT devices having ambient light energy harvesting devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-17 may be rearranged and/or combined into a single component, process, feature, or function or incorporated in several components, processes, or functions. Additional elements, components, processes, and/or functions may also be added without departing from the disclosure. In some implementations, FIGS. 1-17 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An ambient light energy harvesting device, comprising: a semiconductor structure constituting at least a first diode of the ambient light energy harvesting device, the semiconductor structure comprising: a substrate portion of a first doping type; a first plurality of doped regions of the first doping type over the substrate portion; and a second plurality of doped regions of a second doping type over the substrate portion, wherein: the first plurality of doped regions and the second plurality of doped regions are arranged in an alternating manner along a lateral direction.

Clause 2. The ambient light energy harvesting device of clause 1, wherein: a thickness of the first plurality of doped regions and the second plurality of doped regions ranges from 0.2 to 0.4 micrometers (μm), and a thickness of the buried doped structure ranges from 0.4 to 0.6 μm.

Clause 3. The ambient light energy harvesting device of any of clauses 1 to 2, wherein: an entirety of the lower surfaces of the first plurality of doped regions and the lower surfaces of the second plurality of doped regions is in contact with the substrate portion, and a thickness of the first plurality of doped regions and the second plurality of doped regions ranges from 0.4 to 0.8 micrometers (μm).

Clause 4. The ambient light energy harvesting device of any of clauses 1 to 3, further comprising a buried doped structure of the second doping type, wherein: the buried doped structure corresponds to a buried doped layer on and in contact with the substrate portion, and the first plurality of doped regions and the second plurality of doped regions are on and in contact with the buried doped layer.

Clause 5. The ambient light energy harvesting device of any of clauses 1 to 3, further comprising a buried doped structure of the second doping type, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a respective one of the plurality of buried doped fingers, and each one of the lower surfaces of the second plurality of doped regions is in contact with the substrate portion.

Clause 6. The ambient light energy harvesting device of any of clauses 1 to 3, further comprising a buried doped structure of the second doping type, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a first respective portion of the plurality of buried doped fingers and a first respective portion of the plurality of substrate fingers, and each one of the lower surfaces of the second plurality of doped regions is in contact with a second respective portion of the plurality of buried doped fingers and a second respective portion of the plurality of substrate fingers.

Clause 7. The ambient light energy harvesting device of any of clauses 1 to 6, further comprising: a deep trench isolation structure at an edge of the first diode, and wherein a depth of the deep trench isolation structure ranges from 7 to 9 micrometer (μm).

Clause 8. The ambient light energy harvesting device of any of clauses 1 to 7, further comprising: a buried isolation layer below the substrate portion, wherein a depth of an upper surface of the buried isolation layer ranges from 2 to 4 micrometers (μm).

Clause 9. The ambient light energy harvesting device of any of clauses 1 to 8, wherein: the first doping type is a p-doping type, the second doping type is an n-doping type, and the substrate portion comprises silicon with a dopant concentration ranging from 10×10¹² cm⁻³ to 10×10¹⁴ cm⁻³.

Clause 10. The ambient light energy harvesting device of any of clauses 1 to 9, wherein: the first doping type is an n-doping type, the second doping type is a p-doping type, and the substrate portion comprises silicon with a dopant concentration ranging from 10×10¹² cm⁻³ to 10×10¹⁴ cm⁻³.

Clause 11. The ambient light energy harvesting device of any of clauses 1 to 10, wherein: one of the first doping type and the second doping type is a p-doping type based on dopants that comprise arsenic (As), phosphorus (P), antimony (Sb), or a combination thereof, and the other one of the first doping type and the second doping type is an n-doping type based on dopants that comprise boron (B), boron difluoride (BF2), indium (In), or a combination thereof.

Clause 12. The ambient light energy harvesting device of any of clauses 1 to 11, wherein: the semiconductor structure further constitutes a second diode of the ambient light energy harvesting device, and the semiconductor structure further comprise an electrical guard ring structure surrounding the first diode, the second diode, or both.

Clause 13. A method of manufacturing an ambient light energy harvesting device, comprising: forming a semiconductor structure constituting at least a first diode of the ambient light energy harvesting device, comprising: forming a first plurality of doped regions of a first doping type over a substrate portion; and forming a second plurality of doped regions of a second doping type over the substrate portion, wherein: the first plurality of doped regions and the second plurality of doped regions are arranged in an alternating manner along a lateral direction.

Clause 14. The method of clause 13, wherein: a thickness of the first plurality of doped regions and the second plurality of doped regions ranges from 0.2 to 0.4 micrometers (μm), and a thickness of the buried doped structure ranges from 0.4 to 0.6 μm.

Clause 15. The method of any of clauses 13 to 14, wherein: an entirety of the lower surfaces of the first plurality of doped regions and the lower surfaces of the second plurality of doped regions are in contact with the substrate portion, and a thickness of the first plurality of doped regions and the second plurality of doped regions ranges from 0.4 to 0.8 micrometers (μm).

Clause 16. The method of any of clauses 13 to 15, further comprising: forming a buried doped structure prior to the forming the first plurality of doped regions and prior to the forming the second plurality of doped regions.

Clause 17. The method of clause 16, wherein: the buried doped structure corresponds to a buried doped layer on and in contact with the substrate portion, and the first plurality of doped regions and the second plurality of doped regions are on and in contact with the buried doped layer.

Clause 18. The method of clause 16, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a respective one of the plurality of buried doped fingers, and each one of the lower surfaces of the second plurality of doped regions is in contact with the substrate portion.

Clause 19. The method of clause 16, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a first respective portion of the plurality of buried doped fingers and a first respective portion of the plurality of substrate fingers, and each one of the lower surfaces of the second plurality of doped regions is in contact with a second respective portion of the plurality of buried doped fingers and a second respective portion of the plurality of substrate fingers.

Clause 20. The method of clause 16, further comprising: forming a deep trench isolation structure at an edge of the first diode, wherein a depth of the deep trench isolation structure ranges from 7 to 9 micrometer (μm).

Clause 21. The method of any of clauses 13 to 20, further comprising: forming a buried isolation layer below the substrate portion, wherein a depth of an upper surface of the buried isolation layer ranges from 2 to 4 micrometers (μm).

Clause 22. The method of any of clauses 13 to 21, wherein: the first doping type is a p-doping type, the second doping type is an n-doping type, and the substrate portion comprises silicon with a dopant concentration ranging from 10×10¹² cm⁻³ to 10×10¹⁴ cm⁻³.

Clause 23. The method of any of clauses 13 to 22, further comprising: one of the first doping type and the second doping type is a p-doping type based on dopants that comprise arsenic (As), phosphorus (P), antimony (Sb), or a combination thereof, and the other one of the first doping type and the second doping type is an n-doping type based on dopants that comprise boron (B), boron difluoride (BF2), indium (In), or a combination thereof.

Clause 24. An electronic device, comprising: an integrated circuit (IC) die that includes processing circuitry and a first ambient light energy harvesting device configured to supply power to the processing circuitry, wherein the first ambient light energy harvesting device comprises a semiconductor structure constituting at least a first diode of the first ambient light energy harvesting device, and the semiconductor structure comprises: a substrate portion of a first doping type; a first plurality of doped regions of the first doping type over the substrate portion; and a second plurality of doped regions of a second doping type over the substrate portion, wherein: the first plurality of doped regions and the second plurality of doped regions are arranged in an alternating manner along a lateral direction.

Clause 25. The electronic device of clause 24, further comprising a buried doped structure of the second doping type, wherein: the buried doped structure corresponds to a buried doped layer on and in contact with the substrate portion, and the first plurality of doped regions and the second plurality of doped regions are on and in contact with the buried doped layer.

Clause 26. The electronic device of clause 24, further comprising a buried doped structure of the second doping type, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a respective one of the plurality of buried doped fingers, and each one of the lower surfaces of the second plurality of doped regions is in contact with the substrate portion.

Clause 27. The electronic device of clause 24, further comprising a buried doped structure of the second doping type, wherein: the buried doped structure corresponds to a plurality of buried doped fingers on and in contact with the substrate portion, the substrate portion includes a plurality of substrate fingers, the plurality of buried doped fingers and the plurality of substrate fingers are arranged in an alternating manner along the lateral direction, each one of the lower surfaces of the first plurality of doped regions is in contact with a first respective portion of the plurality of buried doped fingers and a first respective portion of the plurality of substrate fingers, and each one of the lower surfaces of the second plurality of doped regions is in contact with a second respective portion of the plurality of buried doped fingers and a second respective portion of the plurality of substrate fingers.

Clause 28. The electronic device of any of clauses 24 to 27, wherein the IC die further comprises: a second ambient light energy harvesting device electrically coupled to the first ambient light energy harvesting device in series or in parallel.

Clause 29. The electronic device of any of clauses 24 to 28, wherein the first ambient light energy harvesting device further comprises: a deep trench isolation structure at an edge of the first diode.

Clause 30. The electronic device of any of clauses 24 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

1. An ambient light energy harvesting device, comprising:
a semiconductor structure constituting at least a first diode of the ambient light energy harvesting device, the semiconductor structure comprising:
a substrate portion;
a first plurality of doped regions of a first doping type over the substrate portion; and
a second plurality of doped regions of a second doping type over the substrate portion,
wherein:
the first plurality of doped regions and the second plurality of doped regions are arranged in an alternating manner along a lateral direction.

2. The ambient light energy harvesting device of claim 1, further comprising a buried doped structure of the second doping type, wherein:
a thickness of the first plurality of doped regions and the second plurality of doped regions ranges from 0.2 to 0.4 micrometers (μm), and
a thickness of the buried doped structure ranges from 0.4 to 0.6 μm.

3. The ambient light energy harvesting device of claim 1, wherein:
an entirety of lower surfaces of the first plurality of doped regions and lower surfaces of the second plurality of doped regions is in contact with the substrate portion, and
a thickness of the first plurality of doped regions and the second plurality of doped regions ranges from 0.4 to 0.8 micrometers (μm).

4. The ambient light energy harvesting device of claim 1, further comprising a buried doped structure of the second doping type, wherein:
the buried doped structure corresponds to a buried doped layer on and in contact with the substrate portion, and
the first plurality of doped regions and the second plurality of doped regions are on and in contact with the buried doped layer.

5. The ambient light energy harvesting device of claim 1, further comprising a buried doped structure of the second doping type, wherein:
the buried doped structure corresponds to a plurality of buried doped fingers on and in contact with the substrate portion,
the substrate portion includes a plurality of substrate fingers, the plurality of buried doped fingers and the plurality of substrate fingers are arranged in an alternating manner along the lateral direction,
each one of lower surfaces of the first plurality of doped regions is in contact with a respective one of the plurality of buried doped fingers, and
each one of lower surfaces of the second plurality of doped regions is in contact with the substrate portion.

6. The ambient light energy harvesting device of claim 1, further comprising a buried doped structure of the second doping type, wherein:
the buried doped structure corresponds to a plurality of buried doped fingers on and in contact with the substrate portion,
the substrate portion includes a plurality of substrate fingers, the plurality of buried doped fingers and the plurality of substrate fingers are arranged in an alternating manner along the lateral direction,
each one of lower surfaces of the first plurality of doped regions is in contact with a first respective portion of the plurality of buried doped fingers and a first respective portion of the plurality of substrate fingers, and
each one of lower surfaces of the second plurality of doped regions is in contact with a second respective portion of the plurality of buried doped fingers and a second respective portion of the plurality of substrate fingers.

7. The ambient light energy harvesting device of claim 1, further comprising:
a deep trench isolation structure at an edge of the first diode,
wherein a depth of the deep trench isolation structure ranges from 7 to 9 micrometer (μm).

8. The ambient light energy harvesting device of claim 1, further comprising:
a buried isolation layer below the substrate portion,
wherein a depth of an upper surface of the buried isolation layer ranges from 2 to 4 micrometers (μm).

9. The ambient light energy harvesting device of claim 1, wherein:
one of the first doping type and the second doping type is a p-doping type based on dopants that comprise arsenic (As), phosphorus (P), antimony (Sb), or a combination thereof, and
an other one of the first doping type and the second doping type is an n-doping type based on dopants that comprise boron (B), boron difluoride (BF₂), indium (In), or a combination thereof.

10. A method of manufacturing an ambient light energy harvesting device, comprising:
forming a semiconductor structure constituting at least a first diode of the ambient light energy harvesting device, comprising:
forming a first plurality of doped regions of a first doping type over a substrate portion; and
forming a second plurality of doped regions of a second doping type over the substrate portion,
wherein:
the first plurality of doped regions and the second plurality of doped regions are arranged in an alternating manner along a lateral direction.

11. The method of claim 10, further comprising:
forming a buried doped structure prior to the forming the first plurality of doped regions and prior to the forming the second plurality of doped regions.

12. The method of claim 11, wherein:
the buried doped structure corresponds to a buried doped layer on and in contact with the substrate portion, and
the first plurality of doped regions and the second plurality of doped regions are on and in contact with the buried doped layer.

13. The method of claim 11, wherein:
the buried doped structure corresponds to a plurality of buried doped fingers on and in contact with the substrate portion,
the substrate portion includes a plurality of substrate fingers, the plurality of buried doped fingers and the plurality of substrate fingers are arranged in an alternating manner along the lateral direction,
each one of lower surfaces of the first plurality of doped regions is in contact with a respective one of the plurality of buried doped fingers, and
each one of lower surfaces of the second plurality of doped regions is in contact with the substrate portion.

14. The method of claim 11, wherein:
the buried doped structure corresponds to a plurality of buried doped fingers on and in contact with the substrate portion,
the substrate portion includes a plurality of substrate fingers, the plurality of buried doped fingers and the plurality of substrate fingers are arranged in an alternating manner along the lateral direction,
each one of lower surfaces of the first plurality of doped regions is in contact with a first respective portion of the plurality of buried doped fingers and a first respective portion of the plurality of substrate fingers, and
each one of lower surfaces of the second plurality of doped regions is in contact with a second respective portion of the plurality of buried doped fingers and a second respective portion of the plurality of substrate fingers.

15. The method of claim 10, further comprising:
forming a deep trench isolation structure at an edge of the first diode,
wherein a depth of the deep trench isolation structure ranges from 7 to 9 micrometer (μm).

16. The method of claim 10, further comprising:
forming a buried isolation layer below the substrate portion,
wherein a depth of an upper surface of the buried isolation layer ranges from 2 to 4 micrometers (μm).

17. An electronic device, comprising:
an integrated circuit (IC) die that includes processing circuitry and a first ambient light energy harvesting device configured to supply power to the processing circuitry, wherein the first ambient light energy harvesting device comprises a semiconductor structure constituting at least a first diode of the first ambient light energy harvesting device, and the semiconductor structure comprises:
a substrate portion;
a first plurality of doped regions of a first doping type over the substrate portion;
a first plurality of doped regions of a first doping type over the substrate portion; and
a second plurality of doped regions of a second doping type over the substrate portion,
wherein:
the first plurality of doped regions and the second plurality of doped regions are arranged in an alternating manner along a lateral direction.

18. The electronic device of claim 17, wherein the IC die further comprises:
a second ambient light energy harvesting device electrically coupled to the first ambient light energy harvesting device in series or in parallel.

19. The electronic device of claim 17, wherein the first ambient light energy harvesting device further comprises:
a deep trench isolation structure at an edge of the first diode.

20. The electronic device of claim 17, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, or a device in an automotive vehicle.
